(19) United States
(12) Patent Application Publication
(10) Pub. No.: US 2024/0371823 A1
(43) Pub. Date: Nov. 7, 2024

(54) METHOD FOR PRODUCING CIRCUIT BOARD AND RESIN SHEET USED THEREIN

(71) Applicant: Ajinomoto Co., Inc., Tokyo (JP)

(72) Inventor: Shu IKEHIRA, Kawasaki-shi (JP)

(73) Assignee: Ajinomoto Co., Inc., Tokyo (JP)

(21) Appl. No.: 18/771,168

(22) Filed: Jul. 12, 2024

Related U.S. Application Data
(63) Continuation of application No. PCT/JP2023/000390, filed on Jan. 11, 2023.

(30) Foreign Application Priority Data
Jan. 13, 2022 (JP) 2022-003660

(51) Int. Cl. H01L 23/00; C09J 7/38; C09J 11/04

(52) U.S. Cl. CPC H01L 24/96; C09J 7/38; C09J 11/04; C09J 2203/326; H01L 2224/96

(57) ABSTRACT

A method for producing a circuit board which includes (X) a step of laminating a resin sheet having a support that has a first surface and a second surface and a resin composition layer formed on the second surface of the support onto a substrate so that the resin composition layer is bonded to the substrate, and satisfies the following conditions (i), (ii-1), and (ii-2):
(i) an ambient pressure is reduced simultaneously with or prior to bonding the resin composition layer to the substrate;
(ii-1) a total specific surface area of an inorganic filler in the resin composition layer is 1.5 m²/g or more (in terms of non-volatile components); and
(ii-2) a surface resistivity of the first surface of the support is 1.0×10¹⁰ Ω/sq. or less,
is capable of suppressing generation of an interface void and an increase in a surface potential of a support even when a substrate having a large area is used.

### CROSS REFERENCES TO RELATED APPLICATIONS

This application is a continuation of International Patent Application No. PCT/JP2023/000390, filed on Jan. 11, 2023, and claims priority to Japanese Patent Application No. 2022-003660, filed on Jan. 13, 2022, both of which are incorporated herein by reference in their entireties.

### BACKGROUND OF THE INVENTION

### Field of the Invention

The present invention relates to methods for producing a circuit board and a resin sheet used therein.

### Discussion of the Background

In the production of a circuit board such as a wafer-level package (WLP) and a panel-level package (PLP), a redistribution layer is generally formed by applying a curable resin material onto a substrate such as a wafer or a panel board by a spin coating method, which is followed by curing it to form an insulating layer, then forming a conductive layer, and then repeating these processes to form multiple layers (see, for example, Japanese Patent Application Laid-open No. 2018-87986, which is incorporated herein by reference in its entirety).

### SUMMARY OF THE INVENTION

As the performance of an electronic device advances, a circuit board of a semiconductor package is required to have a further fine wiring. In order to achieve this, it is required to form an insulating layer having a highly flat surface. In addition, the insulating layer of a circuit board is required to have various properties, such as an excellent dielectric property to suppress a transmission loss when operating in a high-frequency environment, and to suppress a warpage when forming the insulating layer having a large area in production of a WLP and a PLP. These requirements tend to become increasingly stringent in the future.

The inventors of the present invention had attempted to use an insulating material in the form of a resin sheet in order to achieve a high functionality in the insulating layer, such as a superior dielectric property and a low warpage, and to realize the insulating layer having a highly flat surface. Specifically, the inventors studied a technique for forming the insulating layer by laminating and curing a resin composition layer on a substrate such as a wafer using a resin sheet having a resin composition layer on a support. As a result, it was recognized that when the area of the substrate was large, a void tended to be formed at the interface between the resin composition layer and the substrate (hereinafter this is referred to as “interface void”), thereby causing swelling and cracking of the insulating layer during curing, sometimes resulting in failing to produce a desired circuit board.

The inventors of the present invention carried out an extensive investigation to suppress the generation of the interface void even when the insulating material in the form of a resin sheet is applied to a substrate having a large area; as a result, they found that it was possible to achieve the above aim by (a) reducing an ambient pressure simultaneously with or prior to bonding the resin composition layer to the substrate, and (b) controlling a size and a content of an inorganic filler in the resin composition layer such that a total specific surface area of the inorganic filler would be 1.5 m²/g or more (in terms of non-volatile components).

It was also found however that although it was possible to suppress the generation of the interface void by using the techniques of (a) and (b) above, a surface potential of the support increased to a level to cause a concern about the damage to a semiconductor chip, especially when the area of the substrate was increased. This increase in the surface potential tended to be more eminent in the composition of the resin composition layer that was intended to further decrease a dielectric loss tangent and a warpage.

Thus, it is an object of the present invention to provide a method for producing a circuit board and a resin sheet used in the method, with which it is possible to suppress both the generation of the interface void and the increase in the surface potential of the support even when the substrate having a large area is used.

This and other objects, which will become apparent during the following detailed description, have been achieved by the inventor's discovery that it was possible to solve the problems described above by the method for producing a circuit board and the resin sheet having the configurations described blow. The present invention was completed on the basis of these findings.

Specifically, the present invention includes the following.

(1) A method for producing a circuit board, the method comprising:
(X) a step of laminating a resin sheet comprising a support having a first surface and a second surface and a resin composition layer formed on the second surface of the support onto a substrate so that the resin composition layer is bonded to the substrate,
the method satisfying the following conditions (i), (ii-1), and (ii-2):
(i) an ambient pressure is reduced simultaneously with or prior to bonding the resin composition layer to the substrate;
(ii-1) a total specific surface area of an inorganic filler in the resin composition layer is 1.5 m²/g or more (in terms of non-volatile components); and
(ii-2) a surface resistivity of the first surface of the support is 1.0×10¹⁰ Ω/sq. or less.
   (2) The method according to (1), wherein the substrate is (a) a semiconductor wafer comprising an electrode pad surface, (b) a carrier substrate on which a plurality of semiconductor chips that are formed by individualizing the semiconductor wafer of (a) are placed with a distance to each other so as to expose the electrode pad surface, (c) a substrate having a sealing resin that seals the semiconductor chips further formed on the carrier substrate of (b), (d) a substrate having a redistribution layer further formed on the sealing resin of the substrate (c), (e) a carrier substrate on which a plurality of the semiconductor chips formed by individualizing the semiconductor wafer of (a) are placed with a distance to each other such that the electrode pad surface faces the carrier substrate, (f) a semiconductor chip-sealed substrate having the electrode pad surface exposed, which is made by peeling off the carrier substrate after further forming a sealing resin that seals the semiconductor chips on the carrier substrate of (e), or (g) a substrate having a redistribution layer further formed on the side of the electrode pad surface of the semiconductor chip-sealed substrate of (f).
   (3) The method according to (1), wherein the substrate is a substrate with a release layer.
   (4) The method according to any one of (1) to (3), wherein the main surface size (minimum size) of the substrate is 150 mm or more.
   (5) The method according to any one of (1) to (4), comprising, after the step (X), one or more steps selected from:
(1) curing the resin composition layer to form an insulating layer,
(2) perforating the insulating layer,
(3) subjecting the insulating layer to a desmear treatment, and
(4) forming a conductive layer on a surface of the insulating layer.
   (6) The method according to any one of (1) to (5), wherein the resin composition layer comprises a stress relief material.
   (7) The method according to any one of (1) to (6), wherein the circuit board is a wafer-level package or a panel-level package.
   (8) A resin sheet used in a method for producing a circuit board, the method including a step of laminating a resin sheet comprising a resin composition layer to a substrate such that the resin composition layer is bonded to a substrate, the method satisfying the following condition (i):
(i) an ambient pressure is reduced simultaneously with or prior to bonding the resin composition layer to the substrate,
the resin sheet comprising:
a support having a first surface and a second surface and a resin composition layer formed on the second surface of the support, wherein
(ii-i) a total specific surface area of an inorganic filler in the resin composition layer is 1.5 m²/g or more (in terms of non-volatile components), and
(ii-2) a surface resistivity of the first surface of the support is 1.0×10¹⁰ Ω/sq. or less.
   (9) The resin sheet according to (8), wherein the main surface size (minimum size) of the substrate is 150 mm or more.
   (10) The resin sheet according to (8) or (9), wherein the total specific surface area of the inorganic filler in the resin composition layer is 4.0 m²/g or more (in terms of non-volatile components).
   (11) The resin sheet according to any one of (8) to (10), wherein a surface resistivity of the second surface of the support is 1.0×10¹⁰ Ω/sq. or less.
   (12) The resin sheet according to any one of (8) to (11), wherein the resin composition layer comprises a stress relief material.
   (13) The resin sheet according to any one of (8) to (12), wherein a melt viscosity of the resin composition layer at 100° C. is 50,000 poise or less.

### Effect of the Invention

According to the present invention, it is possible to provide a method for producing a circuit board and a resin sheet used in the method, with which it is possible to suppress both the generation of the interface void and the increase in the surface potential of the support, even when the substrate having a large area is used.

### DETAILED DESCRIPTION OF THE PREFERRED EMBODIMENTS

Hereinafter, the present invention will be described in detail with reference to preferred embodiments thereof. However, the present invention is not limited to the embodiments and examples described below. The present invention may be optionally modified for implementation without departing from the scope of claims of the present invention and the scope of equivalents thereof.

### Method for Producing Circuit Board

The method for producing a circuit board according to the present invention (hereinafter simply referred to as the “production method of the present invention”) includes
(X) a step of laminating a resin sheet including a support having a first surface and a second surface and a resin composition layer formed on the second surface of the support onto a substrate such that the resin composition layer is bonded to the substrate, and satisfies the conditions (i), (ii-1), and (ii-2) described below:
(i) an ambient pressure is reduced simultaneously with or prior to bonding the resin composition layer to the substrate;
(ii-1) a total specific surface area of an inorganic filler in the resin composition layer is 1.5 m²/g or more (in terms of non-volatile components); and
(ii-2) a surface resistivity of the first surface of the support is 1.0×10¹⁰ Ω/sq. or less.

As described above, the insulating layer on a circuit board is required to have various properties, such as an excellent dielectric property to suppress a transmission loss when operating in a high frequency environment, and to suppress a warpage when forming the insulating layer having a large area in production of a WLP or a PLP. These requirements tend to become increasingly stringent in the future. In order to satisfy these requirements, the approach from a viewpoint of composition of an insulating material may be conceivable; however, with a conventional insulating material in the form of an ink or a granule, it had been sometimes difficult to sufficiently control an applicability and a melt flowability when applying to a substrate while satisfying the above requirements, so that there had been a limit in forming the insulating layer having a highly flat surface to realize a further fine wiring of a circuit board.

The inventors of the present invention attempted to use an insulating material in the form of a resin sheet to realize the insulating layer that not only sufficiently satisfies the properties required for the insulating layer of a circuit board but also has a highly flat surface. In this regard, in the insulating material in the form of a resin sheet, it was recognized that when applied to the substrate having a large area, there was the case in which the interface void was generated thereby failing to produce an intended circuit board. The inventors of the present invention found that it was possible to suppress the generation of the interface void by modifying the equipment and the process as well as the composition of the insulating material, specifically by (a) reducing an ambient pressure simultaneously with or prior to bonding the resin composition layer to the substrate, and (b) controlling a size and a content of an inorganic filler in the resin composition layer such that a total specific surface area of the inorganic filler would be 1.5 m²/g or more (in terms of non-volatile components). On the other hand, it was found that the techniques of (a) and (b) above generated a new problem that the surface potential of the support increased to the level that causes a concern about the damage to a semiconductor chip, especially when the area of the substrate was increased. It was also found that the problem of the increase in the surface potential tended to be more eminent in the composition of the resin composition layer that was intended to further decrease a dielectric loss tangent and a warpage.

In contrast, in the production method of the present invention that satisfied all the above specific conditions (i), (ii-1), and (ii-2), even when the insulating material in the form of a resin sheet was applied to the substrate having a large area, it was possible to suppress both the generation of the interface void and the increase in the surface potential of the support. In combination with the inherent feature of the approach of adopting the insulating material in the form of a resin sheet, with which it is easy to form an insulating layer having a highly flat surface even when the composition is modified so as to sufficiently satisfy the properties required for the insulating layer of a circuit board, the production method of the present invention significantly contributes to achieving a further fine wiring with still sufficiently satisfying the properties required for the insulating layer of the circuit board.

### Step (X)

The method for producing a circuit board according to the present invention includes

(X) a step of laminating a resin sheet including a support having a first surface and a second surface and a resin composition layer formed on the second surface of the support onto a substrate such that the resin composition layer is bonded to the substrate.

When the circuit board is produced by a chip 1st (Chip-1^{st}) process, the “substrate” used in the step (X) may be a semiconductor wafer provided with an electrode pad surface that is formed of a circuit element having a predetermined function and a plurality of electrode pads electrically connected on the circuit element. With regard to the semiconductor wafer, a silicon (Si) type wafer may be preferable, but the semiconductor wafer is not limited to this. A gallium arsenic (GaAs) type, an indium phosphorous (InP) type, a gallium phosphorous (GaP) type, a gallium nitrite (GaN) type, a gallium tellurium (GaTe) type, a zinc selenium (ZnSe) type, a silicon carbide (SiC) type, or other types of wafer may be used. The chip 1st process is the method in which a semiconductor chip is firstly formed and then a redistribution layer is formed on its electrode pad surface (for example, Japanese Patent Application Laid-open No. 2002-289731 and Japanese Patent Application Laid-open No. 2006-173345, which are incorporated herein by reference in their entireties). In this chip 1st process, especially when producing a package having a fan-out structure, the semiconductor wafer is first individualized into chips, and then, each semiconductor chip is disposed on a carrier substrate such that the chips are separated from each other, which is followed by sealing them by a resin, and then, a redistribution layer is formed over an exposed electrode pad surface and on the surrounding sealing resin layer (for example, Japanese Patent Application Laid-open No. 2012-15191 and Japanese Patent Application Laid-open No. 2015-126123, which are incorporated herein by reference in their entireties). With regard to the carrier substrate, a known substrate used in production of the package having a fan-out structure may be used, in which there is no particular restriction in its type. Illustrative examples thereof may include a glass substrate, a metal substrate, and a plastic substrate. In the embodiment described above, the “substrate” in the step (X) may be the substrate in which individualized semiconductor chips are sealed by a sealing resin around them in such a way that the electrode pad surface thereof is exposed. For example, this substrate may be a carrier substrate on which a plurality of the semiconductor chips formed by individualizing the semiconductor wafer are placed so as to be separated from each other thereby exposing the electrode pad surface, and the sealing resin that seals the semiconductor chips is further placed on the carrier substrate. As it will be described later, the method for producing a circuit board according to the present invention is widely applicable to production of a circuit board that includes the step of laminating a resin sheet onto a substrate, and this method may also be applicable not only when forming (an insulating layer of) a redistribution layer as described above, but also when forming a sealing layer and a solder resist layer. For example, in the case where the sealing layer is formed in the production of a package having a fan-out structure using the chip 1st process, the “substrate” in the step (X) may be a carrier substrate on which a plurality of the semiconductor chips formed by individualizing the semiconductor wafer are placed so as to be separated from each other. As it will be described later, the method for producing a circuit board may be classified into a face-up type and a face-down type from the viewpoint of the chip mounting direction. In the face-up type, the semiconductor chips may be placed such that the electrode pad surface may be exposed, while in the face-down type, the semiconductor chips may be placed such that the electrode pad surface faces the carrier substrate. In the case where a solder resist layer is formed, the step (X) may be carried out at the time when forming a protective layer after a redistribution layer (the production procedure including formation of a conductive layer will be described later) is formed.

Accordingly, the substrate according to one embodiment is (a) a semiconductor wafer having an electrode pad surface, (b) a carrier substrate on which a plurality of semiconductor chips that are formed by individualizing the semiconductor wafer of (a) are placed with a distance to each other so as to expose the electrode pad surface, (c) a substrate having a sealing resin that seals the semiconductor chips further formed on the carrier substrate of (b), (d) a substrate having a redistribution layer further formed on the sealing resin of the substrate (c), (e) a carrier substrate on which a plurality of the semiconductor chips formed by individualizing the semiconductor wafer of (a) are placed with a distance to each other such that the electrode pad surface faces the carrier substrate, (f) a semiconductor chip-sealed substrate having the electrode pad surface exposed, which is made by peeling off the carrier substrate after further forming a sealing resin that seals the semiconductor chips on the carrier substrate of (e), or (g) a substrate having a redistribution layer further formed on the side of the electrode pad surface of the semiconductor chip-sealed substrate of (f). Here, (a) corresponds to the case where (an insulating layer of) a redistribution layer is formed in production of the package having a fan-in structure, (c) and (f) correspond to the case where (an insulating layer of) the redistribution layer is formed in production of a package having a fan-out structure, (b) and (e) correspond to the case where an sealing layer is formed, and (d) and (g) correspond to the case a solder resist layer is formed. In addition, (b) through (d) correspond to the case where the face-up type method is adopted, and (e) through (g) correspond to the case where the face-down type method is adopted.

When the circuit board is produced using a redistribution layer 1st (RDL-1^{st}) process, the “substrate” used in the step (X) may be the substrate with a release layer. The redistribution layer 1st process is the method in which a redistribution layer is firstly formed and then a semiconductor chip is formed on the redistribution layer in the state such that its electrode pad surface is electrically connected to the redistribution layer (for example, Japanese Patent Application Laid-open No. 2015-35551 and Japanese Patent Application Laid-open No. 2015-170767, which are incorporated herein by reference in their entireties). In the redistribution layer 1st process, the redistribution layer is exposed by peeling off the substrate with a release layer after the semiconductor chip is formed on the redistribution layer. This redistribution layer 1st process is particularly suitable for production of the package having the fan-out structure. With regard to the substrate with a release layer, a known substrate used in production of a circuit board by the redistribution layer 1st process may be used, in which there is no particular restriction in its type. Illustrative examples thereof may include a glass substrate with a release layer, a metal substrate with a release layer, and a plastic substrate with a release layer.

Accordingly, in one embodiment, the substrate is the substrates with a release layer.

There is no particular restriction in the size of the substrate; thus, this may be determined in accordance with an intended package design. With regard to the size in the direction parallel to the main surface of the substrate (size in the X-Y direction; this is also simply referred to as “main surface size”), in the case of a circular or a roughly circular substrate (hereinafter these are simply referred to as “circular substrate”), the diameter thereof may be, for example, 100 mm (4 inches) or more, or 125 mm (5 inches) or more. According to the production method of the present invention, the substrate having even a further larger area may be used with suppressing the generation of the interface void and the increase in the surface potential of the support. For example, the diameter of the circular substrate may be 150 mm (6 inches) or more, 200 mm (8 inches) or more, 300 mm (12 inches) or more, or 450 mm (18 inches) or more. There is no particular restriction in the upper limit thereof, so that this may be, for example, 600 mm (24 inches) or less. In the case of a square or a rectangular substrate (hereinafter these are also referred to as “rectangular substrate”), its main surface size (in the case of a rectangle, the size of its short side) may be, for example, 50 mm or more, 75 mm or more, 100 mm or more, or 125 mm or more. According to the production method of the present invention, even when a rectangular substrate is used, the substrate having even a further larger area may be used with suppressing the generation of the interface void and the increase in the surface potential of the support. For example, the main surface size of the rectangular substrate (a short side in the case of a rectangle) may be 150 mm or more, 200 mm or more, 300 mm or more, or 450 mm or more. There is no particular restriction in the upper limit of the main surface size of the rectangular substrate, so that this may be, for example, 1000 mm or less.

Accordingly, in one embodiment, the main surface size (minimum size) of the substrate is 150 mm or more. Note that the “main surface size (minimum size)” used in the substrate refers to the diameter in the case of a circular substrate, and to the size of the short side of the main surface in the case of a rectangular substrate.

As mentioned above, according to the production method of the present invention, the substrate having a large area may be used with suppressing the generation of the interface void and the increase in the surface potential of the support. For example, the area of the substrate (projected area when viewed from a direction perpendicular to the main surface of the substrate) may be 150 cm² or more, 200 cm² or more, 300 cm² or more, 500 cm² or more, 700 cm² or more, 1000 cm² or more, 1500 cm² or more, or the like. There is no particular restriction in the upper limit thereof, so that this may be, for example, 10000 cm² or less, or 8000 cm² or less.

In the step (X), the resin sheet (the detail thereof will be described later) is laminated onto the substrate such that the resin composition layer of the resin sheet is bonded to (in contact with) the substrate.

In the production method of the present invention, an ambient pressure is reduced simultaneously with or prior to bonding the resin composition layer to the substrate (“condition (i)”). By carrying out the step (X) in such a way that the condition (i) is satisfied in combination with the condition (ii-1) to be described later in relation to the resin sheet, it is possible to suppress the generation of the interface void even when the substrate having a large area is used.

The step (X) may be carried out using any laminating equipment as long as the condition (i) is satisfied. The laminating equipment (sheet-attaching equipment) described in, for example, Japanese Patent Application Laid-open No. 2013-229515, and Japanese Patent Application Laid-open No. 2006-310338, which are incorporated herein by reference in their entireties, may be used.

From the viewpoint of suitably suppressing the interface void in combination with the condition (ii-1) to be described later, an ambient pressure (ambient pressure in the chamber in which the resin sheet and the substrate to be processed are stored) is reduced to preferably 200 hPa or less, more preferably 150 hPa or less, and still more preferably 100 hPa or less, 80 hPa or less, 60 hPa or less, 50 hPa or less, 40 hPa or less, or 30 hPa or less. The ambient pressure may be reduced to achieve the pressure described above simultaneously with bonding the resin composition layer to the substrate, or the ambient pressure may be reduced to achieve the pressure described above prior to bonding the resin composition layer to the substrate.

The lamination of the resin sheet onto the substrate in the step (X) is carried out preferably under a heated condition. The heating temperature at the time of laminating the resin sheet onto the substrate is preferably 60° C. or higher, and more preferably 80° C. or higher, or 90° C. or higher, and the upper limit of the heating temperature is preferably 150° C. or lower, and more preferably 140° C. or lower, or 120° C. or lower.

The pressure (compression bonding pressure) at the time of laminating the resin sheet onto the substrate in the step (X) is preferably 0.098 MPa or more, and more preferably 0.29 MPa or more, and the upper limit of the press bonding pressure is preferably 1.77 MPa or less, and more preferably 1.47 MPa or less.

In the step (X), the time (compression bonding time) during lamination of the resin sheet onto the substrate is preferably 20 seconds or longer, and more preferably 30 seconds or longer, and the upper limit of the pressure bonding time is preferably 400 seconds or shorter, and more preferably 300 seconds or shorter.

A member used for compression bonding of the resin sheet onto the substrate (hereinafter, this is also referred to as “compression bonding member”) may be determined as appropriate in accordance with the structure of the laminating equipment. Illustrative examples thereof may include a metal plate and an elastic material such as a rubber.

### Other Steps

The production method of the present invention may further include any conventionally known step for production of a desired circuit board as long as the step (X) is carried out in the way that the conditions (ii-1) and (ii-2) described later are satisfied with regard to the resin sheet and the condition (i) described above is achieved.

Hereinafter, one example of the other steps that may be further included in the production method of the present invention will be described.

In one embodiment, the production method of the present invention includes, after the step (X) as described above, one or more steps selected from
(1) curing the resin composition layer to form an insulating layer,
(2) perforating the insulating layer,
(3) subjecting the insulating layer to a desmear treatment, and
(4) forming a conductive layer on a surface of the insulating layer. For example, in the case that the step (X) is to form (the insulating layer of) the redistribution layer, all the steps (1) through (4) may be carried out after the step (X), and in the case that the step (X) is to form a sealing layer or a solder resist layer, the step (1) may be carried out after the step (X).

### Step (1)

In the step (1), the resin composition layer is cured to form an insulating layer.

There is no particular restriction in the curing condition of the resin composition layer; thus, conditions generally used in formation of an insulating layer of a circuit board may be used.

The condition for curing of the resin composition layer varies depending on the kind and the like of the resin composition; for example, in one embodiment, the curing temperature is preferably in the range of 120° C. to 250° C., more preferably in the range of 150° C. to 240° C., and still more preferably in the range of 180° C. to 230° C. The curing time may be made preferably in the range of 5 minutes to 240 minutes, more preferably in the range of 10 minutes to 150 minutes, and still more preferably in the range of 15 minutes to 120 minutes.

Before curing the resin composition layer, the resin composition layer may be preheated at a temperature lower than the curing temperature. For example, before curing the resin composition layer, the resin composition layer may be preliminarily heated at 50° C. to 120° C., preferably 60° C. to 115° C., and more preferably 70° C. to 110° C., and for the period of 5 minutes or longer, preferably 5 minutes to 150 minutes, more preferably 15 minutes to 120 minutes, and still more preferably 15 minutes to 100 minutes. Preheating is advantageous because it is easier to realize the insulating layer having a low surface roughness after the desmear treatment.

### Step (2)

In the step (2), the insulating layer is perforated. By conducting this step, a hole such as a via hole that conducts through the insulating layer may be formed. The step (2) may be carried out by using a drill, a laser, a plasma, or the like, in accordance with the composition of the resin composition used for forming the insulating layer. The size and shape of the hole may be determined as appropriate in accordance with a design of the circuit board.

### Step (3)

In the step (3), the insulating layer is subjected to a desmear treatment.

This removes the smear that has been generated in the via hole by the perforating process. There is no particular restriction in the desmear treatment, and this may be carried out by any known method. In one embodiment, the desmear treatment may be dry desmear treatment, wet desmear treatment, or a combination of them.

Illustrative examples of the dry desmear treatment include the desmear treatment using a plasma. The desmear treatment using a plasma removes smears that are formed in the via hole by treating the insulating layer with the plasma that is generated by introducing a gas into a plasma generator. There is no restriction in the generation method of the plasma, so that illustrative examples thereof may include a microwave plasma in which the plasma is generated by a microwave, a high-frequency plasma using a radio frequency wave, an ambient pressure plasma that is generated under an ambient pressure, and a vacuum plasma that is generated under a vacuum condition. Among these, a vacuum plasma that is generated under a vacuum condition is preferable. The plasma used in the desmear treatment is preferably an RF plasma that is excited by a high frequency wave.

There is no particular restriction in the gas that is to be made to the plasma as long as this is possible to remove the smear in the via hole. For example, a gas containing SF₆ may be used. In this case, the gas to be made to the plasma may include other gases such as Ar and O₂, in addition to SF₆. In particular, from the viewpoint of easiness to realize the insulating layer having a low surface roughness after the desmear treatment, the gas to be made to the plasma may be preferably a mixed gas containing SF₆ and at least one of Ar and O₂, and more preferably a mixed gas containing SF₆, Ar, and O₂. In the case where a mixed gas of SF₆ with other gases is used, from the viewpoint of easiness to realize the insulating layer having a low surface roughness after the desmear treatment, the mixing ratio (SF₆/other gases: unit is sccm) is preferably in the range of 1/0.01 to 1/1, more preferably in the range of 1/0.05 to 1/1, and still more preferably in the range of 1/0.1 to 1/1.

Although there is no particular restriction in the time for the desmear treatment using the plasma, it is preferably 30 seconds or longer, and more preferably 60 seconds or longer, 90 seconds or longer, or 120 seconds or longer. From the viewpoint of easiness to realize the insulating layer having a low surface roughness after the desmear treatment, the upper limit of the time for the desmear treatment is preferably 10 minutes or shorter, and more preferably 5 minutes or shorter.

The desmear treatment using the plasma may be carried out using commercially available equipment for plasma desmear treatment. Illustrative examples of the commercially available suitable equipment for plasma desmear treatment which is especially useful for production of the circuit board include the plasma dry etching equipment manufactured by Oxford Instruments Inc., the microwave plasma equipment manufactured by Nissin Inc., and the ambient pressure plasma etching equipment manufactured by Sekisui Chemical Co., Ltd.

Also, the dry desmear treatment may be carried out using a dry sandblasting method in which an object to be treated is polished by blowing an abrasive material through a nozzle. The dry sandblasting may be carried out using commercially available dry sandblasting equipment. In the case where a water-soluble abrasive material is used as the abrasive material, when water rinsing is carried out after the dry sandblasting, it is possible to effectively remove the smear without leaving the abrasive material inside the via hole.

From the viewpoint of easiness to realize the insulating layer having a low surface roughness regardless of the composition and the like of the resin composition layer, it is preferable that the desmear treatment is carried out using the dry desmear treatment, especially preferably the desmear treatment using the plasma. Accordingly, in one preferable embodiment, the insulating layer is subjected to the dry desmear treatment, especially preferably to the desmear treatment using the plasma.

Illustrative examples of the wet desmear treatment includes desmear treatment using an oxidant solution. In the case where the desmear treatment is carried out using an oxidant solution, it is preferable to carry out a swelling treatment using a swelling solution, an oxidation treatment using an oxidant solution, and a neutralization treatment using a neutralizing solution, in this order. Illustrative examples of the swelling solution include “Swelling Dip Securiganth P” and “Swelling Dip Securiganth SBU”, which are both manufactured by Atotech Japan K.K. It is preferable to carry out the swelling treatment by immersing the substrate having a via hole formed into the swelling solution heated at 60° C. to 80° C. for 5 minutes to 10 minutes. With regard to the oxidant solution, an aqueous alkaline permanganate solution is preferable. Illustrative examples thereof include a solution having potassium permanganate or sodium permanganate dissolved in an aqueous sodium hydroxide solution. It is preferable to carry out the oxidation treatment using the oxidant solution by immersing the substrate after the swelling treatment into the oxidant solution heated at 60° C. to 80° C. for 10 minutes to 30 minutes. Illustrative examples of the aqueous alkaline permanganate solution that is commercially available include “Concentrate Compact P”, “Concentrate Compact CP”, and “Dosing Solution Securiganth P”, all being manufactured by Atotech Japan K.K. It is preferable to carry out the neutralization treatment with the neutralizing solution by immersing the substrate after the oxidation treatment into the neutralizing solution at 30° C. to 50° C. for 3 minutes to 10 minutes. With regard to the neutralizing solution, an acidic aqueous solution is preferable. Illustrative examples of the solution commercially available include “Reduction Solution Securiganth P”, which is manufactured by Atotech Japan K.K.

Also, the wet desmear treatment may be carried out using a wet sandblasting method, in which an abrasive material and a dispersant are blown through a nozzle to polish the object to be processed. The wet sandblasting may be carried out using commercially available wet sandblasting equipment.

In one preferable embodiment, the insulating layer is subjected to the wet desmear treatment, especially preferably to the desmear treatment using the oxidant solution.

In the case where the dry desmear treatment and the wet desmear treatment are carried out in combination, the dry desmear treatment may be carried out first, or the wet desmear treatment may be carried out first.

The support of the resin sheet may be removed before the step (4). Therefore, it may be removed between the step (X) and the step (1), between the step (1) and the step (2), between the step (2) and the step (3), or after the step (3). From the viewpoint of easiness to realize the insulating layer having a low surface roughness after the desmear treatment, it is preferable to remove the support after the step (2), and more preferably after the step (3).

### Step (4)

In the step (4), a conductive layer is formed on the surface of the insulating layer.

In one embodiment, the conductive layer may be formed by plating. For example, the conductive layer having a desired wiring pattern may be formed by plating the surface of the insulating layer using a conventionally known technique such as a semi-additive method and a full-additive method. From the viewpoint of simplicity in production thereof, it is preferable to form the conductive layer by a semi-additive method. Hereinafter, an example of forming the conductive layer by a semi-additive method will be described.

First, a plating seed layer is formed on the surface of the insulating layer by electroless plating. The plating seed layer includes at least a conductive seed layer. The conductive seed layer is the layer that functions as an electrode in the electrolytic plating method. There is no particular restriction in the conductive material that constitutes the conductive seed layer as long as it exhibits a sufficient conductivity. Illustrative examples of the preferable conductive material include copper, palladium, gold, platinum, silver, aluminum, as well as alloys of these metals. The plating seed layer may also include a diffusion barrier layer. The diffusion barrier layer is the layer that prevents the conductive material that constitutes the conductive seed layer from diffusing into the insulating layer thereby causing a damage to the insulation thereof. There is no particular restriction in the material that constitutes the diffusion barrier layer as long as it can inhibit or prevent the conductive material that constitutes the conductive seed layer from diffusion. Illustrative examples of the preferable material thereof may include titanium, tungsten, tantalum, as well as alloys of these metals. After forming the conductive layer having a desired pattern on the plating seed layer, an unnecessary portion of the plating seed layer other than the conductive layer is removed by etching or the like. At this time, the thinner the thickness of the plating seed layer, the easier it is to remove the unnecessary portion of the plating seed layer, and the more advantageous it is to achieve a fine wiring because it is possible to minimize the erosion of the conductive pattern at the time when the unnecessary portion thereof is removed. The thickness of the plating seed layer is preferably 1000 nm (1 μm) or less, and more preferably 800 nm or less, 600 nm or less, 500 nm or less, 400 nm or less, or 300 nm or less. The plating seed layer may be made further thinner, because with the production method of the present invention it is possible to realize the insulating layer having a highly flat surface. For example, the thickness of the plating seed layer may be made 250 nm or less, 200 nm or less, 150 nm or less, 140 nm or less, 120 nm or less, or 100 nm or less. In the case where the plating seed layer includes a diffusion barrier layer, the “thickness of the plating seed layer” in the present invention means the average thickness of the entire plating seed layer including not only the conductive seed layer but also the diffusion barrier layer. In the case where the plating seed layer includes the diffusion barrier layer, there is no particular restriction in the thickness of the diffusion barrier layer as long as it can inhibit and prevent the conductive material that constitutes the conductive seed layer from diffusion. However, from the viewpoint of contributing to the finer wiring, the thickness thereof is preferably 20 nm or less, more preferably 15 nm or less, and more preferably 10 nm or less. There is no particular restriction in the lower limit of the thickness of the diffusion barrier layer, and it may be, for example, 1 nm or more, 3 nm or more, or 5 nm or more. In this case, the rest portion of the plating seed layer is preferably the conductive seed layer, and the thickness of the conductive seed layer may be determined such that the overall thickness of the plating seed layer falls within the preferable range described above in relation to the thickness of the diffusion barrier layer.

The plating seed layer may be formed either by a dry plating method or by a wet plating method. Illustrative examples of the dry plating method include: physical vapor deposition (PVD) methods such as a sputtering method, an ion plating method, and a vacuum deposition method; and chemical vapor deposition (CVD) methods such as a thermal CVD and a plasma CVD. The wet plating method may include an electroless plating method. From the viewpoint of forming a thin plating seed layer having a further uniform thickness, the dry plating method is preferable. In particular, from the viewpoint of realizing a fine wiring having a superior adhesion strength, the sputtering method is especially preferable.

Next, a mask pattern is formed on the plating seed layer thus formed to expose a part of the plating seed layer corresponding to a desired wiring pattern. After a metal layer is formed on the exposed plating seed layer by electroplating, the mask pattern is removed. There is no particular restriction in the conductive material to be used in the metal layer. In a preferable embodiment, the metal layer includes one or more metals selected from the group consisting of gold, platinum, palladium, silver, copper, aluminum, cobalt, chromium, zinc, nickel, titanium, tungsten, iron, tin, and indium. The metal layer may be a single metal layer or an alloy layer. The alloy layer is, for example, a layer formed from an alloy of two or more metals selected from the group described above (for example, a nickel-chromium alloy, a copper-nickel alloy, and a copper-titanium alloy).

Subsequently, an unnecessary plating seed layer is removed by etching or the like, and the conductive layer having a desired wiring pattern (hereinafter, this is also referred to as “conductive pattern”) may be formed.

According to the production method of the present invention, it is possible to form the conductive pattern having the L/S of preferably 5/5 μm or less, more preferably 4/4 μm or less, and still more preferably 3/3 μm or less, or 2/2 μm or less, and it is still possible to suitably form the conductive pattern having the L/S of 1/1 μm. According to the production method of the present invention, it is possible to form the conductive pattern having a low L/S value as described above with the thickness of preferably 3 μm or less, 2.5 μm or less, 2 μm or less, 1.5 μm or less, or 1 μm or less. The lower limit of the thickness of the conductive pattern may be, for example, 0.5 μm or more, or 0.6 μm or more.

The step (X) and steps (1) through (4) described above are also collectively referred to as a rewiring forming step. By repeating the rewiring forming step, a redistribution layer having a multilayer structure may be formed. In the case where the redistribution layer having the multilayer structure is formed, it is preferable to use the production method of the present invention when forming the redistribution layer on the side of the semiconductor chip (generally, the redistribution layer that is formed firstly in the chip 1st process and the redistribution layer that is formed lastly in the redistribution layer 1st process), and the production method of the present invention may be used in all of the multilayer redistribution layers.

According to the production method of the present invention, it is possible to realize the circuit board such as WLP and PLP by using the substrate having a large area with suppressing the generation of the interface void and the increase in the surface potential of the support.

The production method of the circuit board such as WLP and PLP has been described above with referring to the patent literature. For example, in the case where the WLP having the fan-in structure is formed, by using as the “substrate” the semiconductor wafer provided with an electrode pad surface formed of a circuit element having a predetermined function and a plurality of the electrode pads electrically connected on this circuit element, the step (X) may be carried out such that the surface of the electrode pad is bonded to the resin composition layer. Then, the step (1), the step (2), the step (3), and the step (4) may be carried out in sequence to form the redistribution layer on the surface of the electrode pad surface of the semiconductor wafer. By repeating these steps, it is also possible to form the redistribution layer having a multilayer structure. Then, by forming a board connection terminal such as a bump on the side opposite to the semiconductor wafer of the redistribution layer followed by individualizing it, the WLP having the fan-in structure may be produced.

For example, in the case where the WLP having the fan-out structure is produced, the semiconductor wafer formed of a circuit element having a predetermined function and a plurality of the electrode pads electrically connected on this circuit element is individualized first. Each semiconductor chip is then placed on a carrier substrate (a glass substrate, a metal substrate, a plastic substrate, or the like) such that the chips are placed with a distance to each other, which is then followed by sealing them with a resin to obtain the substrate in which the individualized semiconductor chips are sealed by the sealing resin such that the surface of the electrode pad surface is exposed. Using the substrate described above as the “substrate”, the step (X) may be carried out such that the resin composition layer is bonded to the surface of the substrate on the side of the electrode pad surface. Then, the step (1), the step (2), the step (3), and the step (4) may be carried out in sequence to form a redistribution layer on the surface of the electrode pad surface of the semiconductor chip and the surrounding sealing resin layer. By repeating these steps, it is also possible to form the redistribution layer having a multilayer structure. Then, by forming a board connection terminal such as a bump on the side opposite to the substrate of the redistribution layer, which is then followed by newly individualizing it, the WLP having the fan-out structure may be produced.

In particular, the WLP and PLP having the fan-out structure obtained by the production method of the present invention are advantageous because, coupled with the inherent feature of the fan-out structure that the redistribution layer can be formed in a large area, they can form an extremely fine and dense wiring in a large area still having an insulating layer that sufficiently satisfies a dielectric property and a low warpage, among other things. Thus, in one embodiment, the circuit board produced by the production method of the present invention is the WLP or the PLP, more suitably the WLP having the fan-out structure (FOWLP) or the PLP having the fan-out structure (FOPLP).

From the viewpoints of the aforementioned chip 1st process and the redistribution layer 1st process as well as the chip mounting direction (face-down type and face-up type), the production method of the circuit board such as WLP and PLP has been developed variously. In the process of producing them, the present invention is widely applicable to production of a circuit board that includes the step of laminating the resin sheet onto the substrate, and thus, the present invention relates to a highly versatile technology. For example, as described above, the method for producing a circuit board according to the present invention may be used in formation of the sealing layer and the solder resist layer, in addition to formation of the redistribution layer.

### Resin Sheet

Hereinafter, the resin sheet that may be used in the production method of the present invention (hereinafter also simply referred to as the “resin sheet of the present invention”) will be described.

The resin sheet of the present invention includes a support having a first surface and a second surface and a resin composition layer formed on the second surface of the support, and satisfies the following conditions (ii-1) and (ii-2):
(ii-1) a total specific surface area of an inorganic filler in the resin composition layer is 1.5 m²/g or more (in terms of non-volatile components); and
(ii-2) a surface resistivity of the first surface of the support is 1.0×10¹⁰ Ω/sq. or less.

### Resin Composition Layer

From the viewpoint of suppressing the generation of the interface void in combination with condition (i) described above, the resin composition layer includes the inorganic filler so as to satisfy the condition (ii-1) described above.

### Inorganic Filler

The “total specific surface area of an inorganic filler in the resin composition layer” in the condition (ii-1) means the total surface area of inorganic fillers contained in 1 gram of non-volatile components in the resin composition layer. The total specific surface area of the inorganic filler in the resin composition layer may be calculated using the formula: (A×B)/100, where A [m²/g] is the specific surface area of the inorganic filler and B [% by mass] is the content of the inorganic filler when the non-volatile components in the resin composition layer are considered to be 100% by mass. In the case where multiple types of the inorganic filler are used in combination, the specific surface area of all the inorganic fillers in the resin composition layer may be calculated as A, and the content of all the inorganic fillers may be calculated as B.

From the viewpoint of suppressing the generation of the interface void in combination with the condition (i) described above, the total specific surface area of the inorganic filler in the resin composition layer is 1.5 m²/g or more, preferably 2.0 m²/g or more, more preferably 2.5 m²/g or more, and still more preferably 3.0 m²/g or more, or 3.5 m²/g or more. According to the production method of the present invention that satisfies the condition (ii-1) in combination with the condition (i) described above and further satisfies the condition (ii-2), the total specific surface area of the inorganic filler may be further increased with suppressing the increase in the surface potential of the support. For example, the total specific surface area of the inorganic filler in the resin composition may be increased to 4.0 m²/g or more, 5.0 m²/g or more, 6.0 m²/g or more, 7.0 m²/g or more, 8.0 m²/g or more, or even 9.0 m²/g or more. Thus, in one preferable embodiment, the total specific surface area of the inorganic filler in the resin composition layer is 4.0 m²/g or more. In order to improve the properties of the insulating layer formed, such as a low dielectric loss tangent and a low thermal expansion, it is beneficial to blend the inorganic filler in a high content. Thus, the production method of the present invention, with which the total specific surface area of the inorganic filler can be increased in the resin composition layer with suppressing the increase in the surface potential of the support, eminently contributes to sufficiently satisfying the functions required for the insulating layer of the circuit board.

From the viewpoint of suppressing the increase in the surface potential of the support, the upper limit of the total specific surface area of the inorganic filler in the resin composition layer is preferably 25 m²/g or less, 20 m²/g or less, 18 m²/g or less, 16 m²/g or less, or 15 m²/g or less.

Illustrative examples of the material of the inorganic filler include silica, alumina, glass, cordierite, silicon oxide, barium sulfate, barium carbonate, talc, clay, mica powder, zinc oxide, hydrotalcite, boehmite, aluminum hydroxide, magnesium hydroxide, calcium carbonate, magnesium carbonate, magnesium oxide, boron nitride, aluminum nitride, manganese nitride, aluminum borate, strontium carbonate, strontium titanate, calcium titanate, magnesium titanate, bismuth titanate, titanium oxide, zirconium oxide, barium titanate, barium titanate zirconate, barium zirconate, calcium zirconate, zirconium phosphate, and zirconium phosphate tungstate. Among these, silica is especially preferable. Illustrative examples of the silica include amorphous silica, fused silica, crystalline silica, synthesized silica, and hollow silica. With regard to the silica, spherical silica is preferable. The inorganic filler may be used singly or in combination of two or more of those described above.

Illustrative examples of the commercially available product of the inorganic filler include: “SP60-05” and “SP507-05”, both being manufactured by Nippon Steel Chemical & Material Co., Ltd.; “SC2500 SQ”, “SO-C4”, “SO-C2”, “SO-C1”, “YC100C”, “YA050C”, “YA050C-MJE”, and “YA010C”, all being manufactured by Admatechs Co., Ltd.; “UFP-30”, “DAW-03”, and “FB-105FD”, all being manufactured by Denka Co., Ltd.; “Silfil NSS-3N”, “Silfil NSS-4N”, and “Silfil NSS-5N”, all being manufactured by Tokuyama Corp.; “CellSpheres” and “MGH-005”, both being manufactured by Taiheiyo Cement Corp.; and “S-Feerique” and “BA-1”, both being manufactured by JGC Catalysts and Chemicals Ltd.

From the viewpoint of easiness to realize the insulating layer having a low surface roughness after the desmear treatment, the average particle diameter of the inorganic filler is preferably 3 μm or less, more preferably 2 μm or less, and still more preferably 1 μm or less, 0.8 μm or less, 0.6 μm or less, 0.5 μm or less, 0.4 μm or less, or 0.3 μm or less. Although there is no particular restriction in the lower limit of the average particle diameter thereof, this is preferably 0.01 μm or more, more preferably 0.05 μm or more, and still more preferably 0.07 μm or more, 0.1 μm or more, or 0.2 μm or more. The average particle diameter of the inorganic filler may be measured with a laser diffraction scattering method based on the Mie scattering theory. Specifically, the particle diameter distribution of the inorganic filler on the volume basis is prepared using a laser diffraction scattering type particle diameter distribution measurement apparatus, and the average particle diameter thereof can be measured from the median diameter thus obtained. The measurement sample to be used for this may be obtained by weighing 100 mg of the inorganic filler and 10 g of methyl ethyl ketone into a vial bottle, followed by dispersing this mixture for 10 minutes by means of an ultrasonic wave. The particle diameter distribution of the measurement sample of the inorganic filler on the volume basis was measured with a flow cell method using the light source wavelengths of blue and red by means of the laser diffraction type particle diameter distribution measurement apparatus; then, the average particle diameter thereof was calculated as the median diameter from the particle diameter distribution thus obtained. Illustrative examples of the laser diffraction type particle diameter distribution measurement apparatus include “LA-960” manufactured by Horiba, Ltd.

Although there is no particular restriction in (A) the specific surface area of the inorganic filler as long as this satisfies the preferable range of “the total specific surface area of the inorganic filler in the resin composition layer” described above in relation to (B) the content of the inorganic filler in the resin composition, it is preferably 2 m²/g or more, more preferably 4 m²/g or more, and still more preferably 5 m²/g or more, 6 m²/g or more, 8 m²/g or more, or 10 m²/g or more. Although there is no particular restriction in the upper limit of the specific surface area of the inorganic filler, it is preferably 100 m²/g or less, more preferably 80 m²/g or less, and still more preferably 60 m/g or less, or 50 m²/g or less. The specific surface area of the inorganic filler may be calculated by means of a BET multipoint method, in which a nitrogen gas is adsorbed onto the sample surface in accordance with a BET method using a specific surface area measurement apparatus (Macsorb HM-1210, manufactured by Mountech Co., Ltd.).

The inorganic filler may be either a non-hollow type inorganic filler with the porosity of 0% by volume (preferably a non-hollow type silica) or a hollow type inorganic filler with the porosity of more than 0% by volume (preferably hollow type silica), or may contain both. The inorganic filler may contain only a non-hollow type inorganic filler (preferably a non-hollow type silica), or only a hollow type inorganic filler (preferably a hollow type silica), or a combination of a non-hollow type inorganic filler (preferably a non-hollow type silica) and a hollow type inorganic filler (preferably a hollow type silica). When the inorganic filler includes a hollow type inorganic filler, this is preferable because it is easy to realize the resin composition that has a lower dielectric constant thereby producing a cured product having a further enhanced dielectric property. The porosity of the hollow type inorganic filler is preferably 10% by volume or more, more preferably 15% by volume or more, and still more preferably 20% by volume or more, and the upper limit thereof is preferably 90% by volume or less, more preferably 85% by volume or less, and still more preferably 80% by volume or less, 75% by volume or less, 70% by volume or less, 65% by volume or less, 60% by volume or less, 55% by volume or less, or 50% by volume or less. The porosity P (% by volume) of the inorganic filler is defined as the volume-based ratio of the total volume of one, or two or more voids inside the particle to the volume of the entire particle based on the outer surface of the particle (total volume of voids/volume of particle), and this is calculated, for example, from the following formula (1) using the measured actual density of the inorganic filler, D_{M} (g/cm³), and the theoretical value of the material density of the material that forms the inorganic filler, D_{T} (g/cm³).

$$\\ \begin{matrix}P = ( 1 - \frac{{D}_{M}}{{D}_{T}} ) \times 100 & ( 1 )\end{matrix}$$

The actual density of the inorganic filler may be measured by using, for example, a true density measurement instrument. Illustrative examples of the true density measurement instrument include ULTRAPYCNOMETER 1000 manufactured by QUANTACHROME Instruments Corp. For example, nitrogen is used as the measurement gas.

It is preferable that the inorganic filler is treated by an appropriate surface modifying agent. The surface modification enhances the moisture resistance and dispersion property of the inorganic filler. Illustrative examples of the surface modifying agent include: silane coupling agents such as a vinyl type silane coupling agent, an epoxy type silane coupling agent, a styryl type silane coupling agent, a (meth)acrylic type silane coupling agent, an amino type silane coupling agent, an isocyanurate type silane coupling agent, a ureido type silane coupling agent, a mercapto type silane coupling agent, an isocyanurate type silane coupling agent, and an acid anhydride type silane coupling agent; non-silane coupling-alkoxysilane compounds such as methyl trimethoxy silane and phenyl trimethoxy silane; and a silazane compound. The surface modifying agent may be used singly or in combination of two or more of those described above.

Illustrative examples of the commercially available product of the surface modifying agent include “KBM403” (3-glycidoxypropyl trimethoxysilane), “KBM803” (3-mercaptopropyl trimethoxysilane), “KBE903” (3-aminopropyl triethoxysilane), “KBM573” (N-phenyl-3-aminopropyl trimethoxysilane), and “SZ-31” (hexamethyl disilazane), all of these being manufactured by Shin-Etsu Chemical Co., Ltd.

From the viewpoint of enhancing a dispersion property of the inorganic filler, the degree of the surface modification by means of the surface modifying agent is preferably within a given range. Specifically, 100% by mass of the inorganic filler is treated preferably with 0.2 to 5% by mass of the surface modifying agent.

The degree of the surface modification by the surface modifying agent may be evaluated by the carbon amount per unit surface area of the inorganic filler. In view of enhancing the dispersion property of the inorganic filler, the carbon amount per unit surface area of the inorganic filler is preferably 0.02 mg/m² or more, more preferably 0.1 mg/m² or more, and still more preferably 0.2 mg/m² or more. On the other hand, from the viewpoint of preventing the increase in the melt viscosity of the resin composition layer, the carbon amount is preferably 1.0 mg/m² or less, more preferably 0.8 mg/m² or less, and still more preferably 0.5 mg/m² or less. The carbon amount per unit surface area of the inorganic filler may be measured after the inorganic filler whose surface has been treated is cleaned by a solvent (for example, methyl ethyl ketone (MEK)). Specifically, after a sufficient amount of MEK as the solvent is added to the inorganic filler whose surface has been treated with a surface modifying agent, this is cleaned by means of an ultrasonic wave at 25° C. for 5 minutes. The supernatant solution thereof is removed; and then, after the solid component is dried, the carbon amount per unit surface area of the inorganic filler may be measured using a carbon analysis apparatus. The carbon analysis apparatus such as “EMIA-320V” manufactured by Horiba, Ltd. may be used.

There is no particular restriction in the content (B) of the inorganic filler in the resin composition layer as long as it satisfies the suitable range of “the total specific surface area of the inorganic filler in the resin composition layer” described above in relation to the specific surface area (A) of the inorganic filler. However, from the viewpoint of realizing the insulating layer having superior properties such as a low dielectric loss tangent and a low thermal expansion coefficient, when the non-volatile components in the resin composition layer is defined as 100% by mass, the content (B) is preferably 30% by mass or more, more preferably 40% by mass or more, and still more preferably 45% by mass or more, 50% by mass or more, 55% by mass or more, 60% by mass or more, 65% by mass or more, 66% by mass or more, 68% by mass or more, 70% by mass or more, 72% by mass or more, 74% by mass or more, or 75% by mass or more. Also, the upper limit of the content of the inorganic filler is preferably 90% by mass or less, and more preferably 85% by mass or less, 84% by mass or less, 82% by mass or less, or 80% by mass or less.

### Curable Resin

In the resin sheet of the present invention, the resin composition layer includes a curable resin as the resin. There is no particular restriction in the curable resin as long as it can be cured to form the insulating layer. From the viewpoint of superior properties including an insulating property and a heat resistance, the curable resin is preferably one or more resins selected from the group consisting of a thermosetting resin and a radically polymerizable resin.

Illustrative examples of the thermosetting resin include an epoxy resin, a benzocyclobutene resin, an epoxy acrylate resin, a urethane acrylate resin, a urethane resin, a polyimide resin, a melamine resin, and a silicone resin. The thermosetting resin may be used singly, or as a combination of two or more of those described above. In particular, from the viewpoint of sufficiently satisfying the properties required for the insulating layer of the circuit board, such as a superior dielectric property and a low warpage, it is preferable that the curable resin includes an epoxy resin.

There is no particular restriction in the epoxy resin as long as this has one or more (preferably two or more) epoxy groups in one molecule. Illustrative examples of the epoxy resin include a bisphenol A type epoxy resin, a bisphenol F type epoxy resin, a bisphenol S type epoxy resin, a bisphenol AF type epoxy resin, a phenol novolac type epoxy resin, a tert-butyl-catechol type epoxy resin, a naphthol type epoxy resin, a naphthalene type epoxy resin, a naphthylene ether type epoxy resin, a glycidylamine type epoxy resin, a glycidyl ester type epoxy resin, a cresol novolac type epoxy resin, a biphenyl type epoxy resin, a phenol aralkyl type epoxy resin, a biphenyl aralkyl type epoxy resin, a fluorene-skeleton type epoxy resin, a dicyclopentadiene type epoxy resin, an anthracene type epoxy resin, a linear aliphatic epoxy resin, an epoxy resin having a butadiene structure, an alicyclic epoxy resin, a heterocyclic epoxy resin, an epoxy resin having a spiro ring, a cyclohexanedimethanol type epoxy resin, a trimethylol type epoxy resin, and a halogenated epoxy resin.

The epoxy resin may be classified into a liquid epoxy resin that is in the state of liquid at a temperature of 20° C. (hereinafter referred to as “liquid epoxy resin”) and a solid epoxy resin that is in the state of solid at a temperature of 20° C. (hereinafter referred to as “solid epoxy resin”). In the resin sheet of the present invention, the resin composition layer may contain, as the curable resin, only the liquid epoxy resin, or only the solid epoxy resin, or a combination of the liquid epoxy resin and the solid epoxy resin. When the liquid epoxy resin and the solid epoxy resin are included in combination, the blending ratio thereof (liquid: solid) in terms of mass ratio may be made in the range of 20:1 to 1:20 (preferably in the range of 10:1 to 1:10, more preferably in the range of 3:1 to 1:3).

With regard to the solid epoxy resin, the solid epoxy resin having three or more epoxy groups in one molecule is preferable, and an aromatic solid epoxy resin having three or more epoxy groups in one molecule is more preferable. The solid epoxy resin is preferably a bixylenol type epoxy resin, a naphthalene type epoxy resin, a naphthalene tetrafunctional type epoxy resin, a naphthol novolac type epoxy resin, a cresol novolac type epoxy resin, a dicyclopentadiene type epoxy resin, a trisphenol type epoxy resin, a naphthol type epoxy resin, a biphenyl type epoxy resin, a naphthylene ether type epoxy resin, an anthracene type epoxy resin, a bisphenol A type epoxy resin, a bisphenol AF type epoxy resin, a phenol aralkyl type epoxy resin, a tetraphenylethane type epoxy resin, a phenol phthalimidine type epoxy resin, or a phenolphthalein type epoxy resin.

Specifically, illustrative examples of the solid epoxy resin include “HP4032H” (naphthalene type epoxy resin) manufactured by DIC Corp.; “HP-4700” and “HP-4710” (naphthalene type tetrafunctional epoxy resins), which are both manufactured by DIC Corp.; “N-690” (cresol novolac type epoxy resin) manufactured by DIC Corp.; “N-695” (cresol novolac type epoxy resin) manufactured by DIC Corp.; “HP-7200”, “HP-7200HH”, “HP-7200H”, and “HP-7200L” (dicyclopentadiene type epoxy resin), which are all manufactured by DIC Corp.; “EXA-7311”, “EXA-7311-G3”, “EXA-7311-G4S”, “HP6000”, and “HP6000L” (naphthylene ether type epoxy resin), which are all manufactured by DIC Corp.; “EPPN-502H” (trisphenol type epoxy resin) manufactured by Nippon Kayaku Co., Ltd.; “NC7000L” (naphthol novolac type epoxy resin) manufactured by Nippon Kayaku Co., Ltd.; “NC3000H”, “NC3000”, “NC3000L”, “NC3000FH”, and “NC3100” (biphenyl type epoxy resin), which are all manufactured by Nippon Kayaku Co., Ltd.; “ESN475V” (naphthalene type epoxy resin) manufactured by Nippon Steel Chemical & Materials Co., Ltd.; “ESN485” (naphthol type epoxy resin) manufactured by Nippon Steel Chemical & Materials Co., Ltd.; “ESN375” (dihydroxynaphthalene type epoxy resin) manufactured by Nippon Steel Chemical & Materials Co., Ltd.; “YX4000H”, “YX4000”, “YX4000HK”, and “YL7890” (bixylenol type epoxy resin), which are all manufactured by Mitsubishi Chemical Corp.; “YL6121” (biphenyl type epoxy resin) manufactured by Mitsubishi Chemical Corp.; “YX8800” (anthracene type epoxy resin) manufactured by Mitsubishi Chemical Corp.; “YX7700” (phenol aralkyl type epoxy resin) manufactured by Mitsubishi Chemical Corp.; “PG-100” and “CG-500”, which are both manufactured by Osaka Gas Chemicals Co., Ltd.; “YX7760” (bisphenol AF type epoxy resin) manufactured by Mitsubishi Chemical Corp.; “YL7800” (fluorene type epoxy resin) manufactured by Mitsubishi Chemical Corp.; “jER1010” (bisphenol A type epoxy resin) manufactured by Mitsubishi Chemical Corp.; “jER1031S” (tetraphenylethane type epoxy resin) manufactured by Mitsubishi Chemical Corp.; and “WHR991S” (phenol phthalimidine type epoxy resin) manufactured by Nippon Kayaku Co., Ltd. These may be used singly or as a combination of two or more of those described above.

With regard to the liquid epoxy resin, the liquid epoxy resin having two or more epoxy groups in one molecule is preferable. The liquid epoxy resin is preferably a bisphenol A type epoxy resin, a bisphenol F type epoxy resin, a bisphenol AF type epoxy resin, a hydrogenated bisphenol A type epoxy resin, a naphthalene type epoxy resin, a glycidyl ester type epoxy resin, a glycidyl amine type epoxy resin, a phenol novolac type epoxy resin, an alicyclic epoxy resin having an ester skeleton, a cyclohexane type epoxy resin, a cyclohexane dimethanol type epoxy resin, and an epoxy resin having a butadiene structure.

Specifically, illustrative examples of the liquid epoxy resin include “HP4032”, “HP4032D”, and “HP4032SS” (these are naphthalene type epoxy resins) manufactured by DIC Corp.; “828US”, “828EL”, “jER828EL”, and “825” (these are bisphenol A type epoxy resins) manufactured by Mitsubishi Chemical Corp.; “jER807” and “1750” (both are bisphenol F type epoxy resins) manufactured by Mitsubishi Chemical Corp.; “jER152” (phenol novolac type epoxy resin) manufactured by Mitsubishi Chemical Corp.; “630”, “630LSD”, and “604” (these are glycidyl amine type epoxy resins) manufactured by Mitsubishi Chemical Corp.; “ED-523T” (glycyrol type epoxy resin) manufactured by Adeka Corp.; “EP-3950L” and “EP-3980S” (both are glycidylamine type epoxy resins) manufactured by Adeka Corp.; “EP-4088S” (dicyclopentadiene type epoxy resin) manufactured by Adeka Corp.; “ZX1059” (mixture of bisphenol A type epoxy resin and bisphenol F type epoxy resin) manufactured by Nippon Steel Chemical & Material Co., Ltd.; “EX-721” (glycidyl ester type epoxy resin) manufactured by Nagase ChemteX Corp.; “Celloxide 2021P” (alicyclic epoxy resin having an ester skeleton) manufactured by Daicel Corp.; “PB-3600” manufactured by Daicel Corp., “JP-100” and “JP-200” (epoxy resins having a butadiene skeleton) manufactured by Nippon Soda Co., Ltd.; “ZX1658” and “ZX1658GS” (both are 1,4-glycidylcyclohexane type epoxy resins) manufactured by Nippon Steel Chemical & Material Co., Ltd.; “YX8000” (hydrogenated bisphenol A type epoxy resin) manufactured by Mitsubishi Chemical Corp.; and “KF-101” (epoxy-modified silicone resin) manufactured by Shin-Etsu Chemical Co., Ltd. These may be used singly or as a combination of two or more of those described above.

The epoxy equivalent of the epoxy resin is preferably in the range of 50 g/eq. to 2000 g/eq., more preferably in the range of 60 g/eq. to 1000 g/eq., and still more preferably in the range of 80 g/eq. to 500 g/eq. The epoxy equivalent is a mass of the epoxy resin including one equivalent of the epoxy group, and this may be measured in accordance with JIS K7236.

The weight-average molecular weight (Mw) of the epoxy resin is preferably in the range of 100 to 5,000, more preferably in the range of 250 to 3,000, and still more preferably in the range of 400 to 1, 500. The Mw of the epoxy resin may be measured by the GPC method in terms of a polystyrene.

There is no particular restriction in the radically polymerizable resin as long as this has one or more (preferably two or more) radically polymerizable unsaturated groups in one molecule. Illustrative examples of the radically polymerizable resin include resins having one or more of the following groups as the radically polymerizable unsaturated group, i.e., a maleimide group, a vinyl group, an allyl group, a styryl group, a vinyl phenyl group, an acryloyl group, a methacryloyl group, a fumaroyl group, and a maleoyl group. Among these, from the viewpoint of sufficiently satisfying the properties required for the insulating layer of the circuit board, such as a superior dielectric property and a low warpage, it is preferable that the curable resin includes one or more resins selected from a maleimide resin, a (meth) acrylic resin, and a styryl resin.

There is no particular restriction in the maleimide resin as long as this has one or more (preferably two or more) maleimide groups (2,5-dihydro-2,5-dioxo-1H-pyrrol-1-yl group) in one molecule. Illustrative examples of the maleimide resin include: (1) maleimide resins containing an aliphatic skeleton having 36 carbon atoms derived from a dimer diamine, such as “BMI-3000J”, “BMI-5000”, “BMI-1400”, “BMI-1500”, “BMI-1700”, and “BMI-689” (all are manufactured by Designer Molecules Inc.); (2) maleimide resins containing an indane skeleton described in Journal of Technical Disclosure (Japan Institute of Invention and Innovation) No. 2020-500211 (commercially available products include “MIR-5000-60T” (manufactured by Nippon Kayaku Co., Ltd.)); and (3) maleimide resins containing an aromatic ring skeleton bonded directly to the nitrogen atom of the maleimide group, such as “MIR-3000-70MT” (manufactured by Nippon Kayaku Co., Ltd.), “BMI-4000” (manufactured by Daiwakasei Industry Co., Ltd.), and “BMI-80” (manufactured by K-I Chemical Industry Co., Ltd.).

There is no particular restriction in the (meth)acrylic resin, so that a monomer or an oligomer thereof may be used as long as they have one or more (preferably two or more) (meth)acryloyl groups in one molecule. The term “(meth)acryloyl group” is a generic term for an acryloyl group and a methacryloyl group. Illustrative examples of the methacrylic resin include, besides a (meth)acrylate monomer, “A-DOG” (manufactured by Shin-Nakamura Chemical Co., Ltd.), “DCP-A” (manufactured by Kyoeisha Chemical Co., Ltd.), and “NPDGA”, “FM-400”, “R-687”, “THE-330”, “PET-30”, and “DPHA” (all are manufactured by Nippon Kayaku Co., Ltd.).

There is no particular restriction in the styryl resin, so that a monomer or an oligomer thereof may be used as long as they have one or more (preferably two or more) styryl groups or vinyl phenyl groups in one molecule. Illustrative examples of the styryl resin include “OPE-2St”, “OPE-2St 1200”, and “OPE-2St 2200” (all are manufactured by Mitsubishi Gas Chemical Company Inc.).

In the resin sheet of the present invention, the resin composition layer may include, as the curable resin, only a thermosetting resin, or only a radically polymerizable resin, or a combination of the thermosetting resin and the radically polymerizable resin.

The content of the curable resin in the resin composition relative to 100% by mass of the resin components in the resin composition is preferably 5% by mass or more, more preferably 10% by mass or more, and still more preferably 12% by mass or more, 14% by mass or more, or 15% by mass or more. There is no particular restriction in the upper limit of the content thereof, so that this may be determined in accordance with the properties required for the resin composition; thus, this may be, for example, 80% by mass or less, 70% by mass or less, 60% by mass or less, or 50% by mass or less.

In the present invention, the “resin component” refers to the non-volatile components that constitute the resin composition layer excluding the inorganic filler described later.

In the resin composition layer, the content of the epoxy resin relative to 100% by mass of the non-volatile components of the curable resin is preferably 40% by mass or more, more preferably 50% by mass or more, and still more preferably 55% by mass or more, 60% by mass or more, 65% by mass or more, or 70% by mass or more. There is no particular restriction in the upper limit of the content of the epoxy resin in the curable resin, and it may be 100% by mass, 95% by mass or less, 90% by mass or less, or the like.

### Curing Agent

In the resin sheet of the present invention, the resin composition layer may include a curing agent. The curing agent usually has the function of curing the resin composition by reacting with the curable resin.

Illustrative examples of the curing agent include an active ester type curing agent, a phenol type curing agent, a naphthol type curing agent, an acid anhydride type curing agent, a cyanate ester type curing agent, a carbodiimide type curing agent, and an amine type curing agent. The curing agent may be used singly or as a combination of two or more of those described above.

In particular, from the viewpoint of being able to bring about a cured product (insulating layer) having a superior dielectric property and conductor adhesion property, it is preferable that the curing agent includes one or more agents selected from the group consisting of an active ester type curing agent, a phenol type curing agent, and a naphthol type curing agent, and especially from the viewpoint of being able to bring about a cured product having a superior dielectric property, it is especially preferable to include an active ester type curing agent Accordingly, in one embodiment, the curing agent includes one or more curing agents selected from the group consisting of an active ester type curing agent, a phenol type curing agent, and a naphthol type curing agent; and it is more preferable to include an active ester type curing agent.

With regard to the active ester type curing agent, a compound having one or more active ester groups in one molecule may be used. Among the active ester type curing agents, the compound having two or more highly reactive ester groups in one molecule is preferable. Thus, illustrative examples of the highly reactive ester group include a phenol ester, a thiophenol ester, an N-hydroxylamine ester, and an ester of a heterocyclic hydroxy compound. The active ester type curing agent is preferably a compound that is obtained by a condensation reaction of a carboxylic acid compound and/or a thiocarboxylic acid compound with a hydroxy compound and/or with a thiol compound. In particular, from the viewpoint to enhance a heat resistance, the active ester type curing agent obtained from a carboxylic acid compound and a hydroxy compound is preferable, while an active ester type curing agent obtained from a carboxylic acid compound and a phenol compound and/or a naphthol compound is more preferable.

Illustrative examples of the carboxylic acid compound include benzoic acid, acetic acid, succinic acid, maleic acid, itaconic acid, phthalic acid, isophthalic acid, terephthalic acid, and pyromellitic acid.

Illustrative examples of the phenol compound or the naphthol compound include hydroquinone, resorcin, bisphenol A, bisphenol F, bisphenol S, phenolphthalin, methylated bisphenol A, methylated bisphenol F, methylated bisphenol S, phenol, o-cresol, m-cresol, p-cresol, catechol, α-naphthol, β-naphthol, 1,5-dihydroxy naphthalene, 1,6-dihydroxy naphthalene, 2,6-dihydroxy naphthalene, dihydroxy benzophenone, trihydroxy benzophenone, tetrahydroxy benzophenone, phloroglucin, benzene triol, a dicyclopentadiene type diphenol compound, and phenol novolac. Here, the “dicyclopentadiene type diphenol compound” means a diphenol compound obtained by condensation of one dicyclopentadiene molecule with two phenol molecules.

Specifically, illustrative examples of the preferable active ester type curing agent include an active ester type curing agent containing a dicyclopentadiene type diphenol structure, an active ester type curing agent containing a naphthalene structure, an active ester type curing agent containing an acetylated phenol novolac, and an active ester type curing agent containing a benzoylated phenol novolac. Among them, the active ester type curing agent containing a naphthalene structure and the active ester type curing agent containing a dicyclopentadiene type diphenol structure are more preferable. Here, the “dicyclopentadiene type diphenol structure” means the divalent structure unit formed of phenylene-dicyclopentylene-phenylene.

Illustrative examples of the commercially available product of the active ester compound include: as the active ester compound containing a dicyclopentadiene type diphenol structure, “EXB9451”, “EXB9460”, “EXB9460S”, “HPC-8000L-65TM”, “HPC-8000-65T”, and “HPC-8000H-65TM”, all being manufactured by DIC Corp.; as the active ester compound containing a naphthalene structure, “EXB-8100L-65T”, “EXB-9416-70BK”, and “HPC-8150-62T”, all being manufactured by DIC Corp.; as the active ester compound containing phosphorous, “EXB9401” manufactured by DIC Corp.; as the active ester compound containing an acetylated phenol novolac, “DC808” manufactured by Mitsubishi Chemical Corp.; as the active ester compound containing a benzoylated phenol novolac, “YLH1026”, “YLH1030”, and “YLH1048”, all being manufactured by Mitsubishi Chemical Corp.; and as the active ester compound containing a styryl group and a naphthalene structure, “PC1300-02-65MA” manufactured by Air Water Inc.

With regard to the phenol type curing agent and the naphthol type curing agent, from the viewpoint of the heat resistance and the water resistance, a curing agent having a novolac structure is preferable. From the viewpoint of the adhesion property with a conductive layer, a nitrogen-containing phenol type curing agent and a nitrogen-containing naphthol type curing agent are preferable, while a phenol type curing agent having a triazine skeleton and a naphthol type curing agent having a triazine skeleton are more preferable.

Specifically, illustrative examples of the phenol type curing agent and the naphthol type curing agent include “MEH-7700”, “MEH-7810”, “MEH-7851”, and “MEH-8000H”, all being manufactured by Meiwa Plastic Industries, Ltd.; “NHN”, “CBN”, and “GPH”, all being manufactured by Nippon Kayaku Co., Ltd.; “SN-170”, “SN-180”, “SN-190”, “SN-475”, “SN-485”, “SN-495”, “SN-495V”, “SN-375”, and “SN-395”, all being manufactured by Nippon Steel Chemical & Material Co., Ltd.; “TD-2090”, “LA-7052”, “LA-7054”, “LA-1356”, “LA-3018-50P”, “EXB-9500”, “HPC-9500”, “KA-1160”, “KA-1163”, and “KA-1165”, all being manufactured by DIC Corp.; and “GDP-6115L”, “GDP-6115H”, and “ELPC75”, all being manufactured by Gunei Chemical Industry Co., Ltd.

The acid anhydride type curing agent may be the curing agent having one or more acid anhydride groups in one molecule. Specifically, illustrative examples of the acid anhydride type curing agent include phthalic anhydride, tetrahydrophthalic anhydride, hexahydrophthalic anhydride, methyltetrahydrophthalic anhydride, methylhexahydrophthalic anhydride, methyl nadic anhydride, hydrogenated methyl nadic anhydride, trialkyltetrahydrophthalic anhydride, dodecenylsuccinic anhydride, 5-(2,5-dioxotetrahydro-3-furanyl)-3-methyl-3-cyclohexene-1,2-dicarboxylic anhydride, trimellitic anhydride, pyromellitic anhydride, benzophenone tetracarboxylic dianhydride, biphenyl tetracarboxylic dianhydride, naphthalene tetracarboxylic dianhydride, oxydiphthalic dianhydride, 3,3′-4,4′-diphenylsulfone tetracarboxylic dianhydride, 1, 3, 3a, 4,5,9b-hexahydro-5-(tetrahydro-2,5-dioxo-3-furanyl)-naphtho [1,2-C]furan-1,3-dione, ethyleneglycol bis(anhydrotrimellitate), and polymer-type acid anhydrides such as a styrene-maleic acid resin, which is a copolymer of styrene and maleic acid. Illustrative examples of the commercially available acid anhydride type curing agent include “MH-700” manufactured by New Japan Chemical Co., Ltd.

Illustrative examples of the cyanate ester type curing agent include bifunctional cyanate resins such as bisphenol A dicyanate, polyphenol cyanate, oligo(3-methylene-1,5-phenylenecyanate), 4,4′-methylenebis(2,6-dimethylphenylcyanate), 4,4′-ethylidene diphenyl dicyanate, hexafluorobisphenol A dicyanate, 2,2-bis(4-cyanate)phenylpropane, 1,1-bis(4-cyanatephenylmethane), bis(4-cyanate-3,5-dimethylphenyl) methane, 1,3-bis(4-cyanatephenyl-1-(methylethylidene))benzene, bis(4-cyanatephenyl)thioether, and bis(4-cyanatephenyl) ether; polyfunctional cyanate resins derived from a phenol novolac, a cresol novolac, and the like; and a prepolymer in which these cyanate resins are partially made to triazine. Specifically, illustrative examples of the cyanate ester type curing agent include “PT30” and “PT60” (both are phenol novolac type polyfunctional cyanate ester resins); “ULL-950S” (a polyfunctional cyanate ester); “BA230” and “BA230S75” (prepolymers in which part or all of bisphenol A dicyanate is made to triazine so as to be a trimer), all of these being manufactured by Lonza Japan Ltd.

Specifically, illustrative examples of the carbodiimide type curing agent include Carbodilite (registered trade mark) V-03 (carbodiimide equivalent of 216 g/eq.), V-05 (carbodiimide equivalent of 262 g/eq.), V-07 (carbodiimide equivalent of 200 g/eq.), and V-09 (carbodiimide equivalent of 200 g/eq.) all of these being manufactured by Nisshinbo Chemical, Inc.; and Stabaxol (registered trade mark) P (carbodiimide equivalent of 302 g/eq.) manufactured by Rhein Chemie GmbH.

With regard to the amine type curing agent, the curing agent having one or more amino groups in one molecule may be mentioned. Illustrative examples thereof include an aliphatic amine, a polyether amine, an alicyclic amine, and an aromatic amine. Specifically, illustrative examples of the amine type curing agent include 4,4′-methylenebis(2,6-dimethylaniline), diphenyl diaminosulfone, 4,4′-diaminodiphenylmethane, 4,4′-diaminodiphenyl sulfone, 3,3′-diaminodiphenyl sulfone, m-phenylenediamine, m-xylenediamine, diethyltoluenediamine, 4,4′-diaminodiphenyl ether, 3,3′-dimethyl-4, 4′-diaminobiphenyl, 2,2′-dimethyl-4, 4′-diaminobiphenyl, 3, 3′-dihydroxybenzidine, 2, 2-bis(3-amino-4-hydroxyphenyl) propane, 3, 3-dimethyl-5, 5-diethyl-4, 4-diphenylmethanediamine, 2, 2-bis(4-aminophenyl) propane, 2, 2-bis(4-(4-aminophenoxy)phenyl) propane, 1, 3-bis(3-aminophenoxy)benzene, 1, 3-bis(4-aminophenoxy)benzene, 1, 4-bis(4-aminophenoxy)benzene, 4,4′-bis(4-aminophenoxy) biphenyl, bis(4-(4-aminophenoxy)phenyl) sulfone, and bis(4-(3-aminophenoxy)phenyl) sulfone. Commercially available amine type curing agents may be used. Illustrative examples thereof include “KAYABOND C-200S”, “KAYABOND C-100”, “KAYAHARD A-A”, “KAYAHARD A-B”, and “KAYAHARD A-S”, all being manufactured by Nippon Kayaku Co. Ltd., as well as “Epicure W” manufactured by Mitsubishi Chemical Corp.

From the viewpoint of being able to bring about a cured product having a superior dielectric property and conductor adhesion property, the content of the curing agent in the resin composition relative to 100% by mass of the resin components in the resin composition is preferably 5% by mass or more, more preferably 10% by mass or more, and still more preferably 15% by mass or more, 20% by mass or more, 25% by mass or more, or 30% by mass or more. There is no particular restriction in the upper limit of the content, and it may be determined in accordance with the properties required for the resin composition; therefore, this is, for example, 70% by mass or less, 60% by mass or less, or 55% by mass or less.

As mentioned above, from the viewpoint of bringing about a cured product having a superior dielectric property, it is preferable for the curing agent to include the active ester type curing agent. In the case where the resin composition layer includes the active ester type curing agent as the curing agent, from the viewpoint of obtaining the cured product having a further superior dielectric property, the content of the active ester type curing agent in the curing agent relative to 100% by mass of the non-volatile components of the curing agent is preferably 50% by mass or more, more preferably 60% by mass or more, and still more preferably 70% by mass or more, 75% by mass or more, or 80% by mass or more. There is no particular restriction in the upper limit of the content of the active ester type curing agent in the curing agent; thus, this may be 100% by mass, but may also be 95% by mass or less, 90% by mass or less, or the like.

In the case where the resin composition layer includes the active ester type curing agent as the curing agent, from the viewpoint of exhibiting a further superior dielectric property, the mass ratio of the active ester type curing agent to the curable resin (active ester type curing agent/curable resin) is preferably 0.5 or more, more preferably 0.6 or more, and still more preferably 0.7 or more, or 0.8 or more. The upper limit of the mass ratio (active ester type curing agent/curable resin) may be 2 or less, 1.8 or less, 1.6 or less, 1.5 or less, or the like.

In one preferable embodiment, the resin composition layer includes the inorganic filler, the curable resin, and the curing agent, and satisfies the condition (ii-1) described earlier. The resin composition layer may further include one or more materials selected from the group consisting of a stress relief material and a curing accelerator to the extent that the above condition (ii-1) is satisfied and the advantageous effects of the invention are not impaired.

### Stress Relief Material

The resin composition layer may further include a stress relief material. By including the stress relief material, it is possible to suppress the warpage even when forming the insulating layer on the substrate having a large area.

The stress relief material is preferably a resin having one or more structures selected from the group consisting of a polybutadiene structure, a polysiloxane structure, a poly(meth)acrylate structure, a polyalkylene structure, a polyalkyleneoxy structure, a polyisoprene structure, a polyisobutylene structure, and a polycarbonate structure; the material is more preferably a resin having one, or two or more structures selected from the group consisting of a polybutadiene structure, a poly(meth)acrylate structure, a polyalkyleneoxy structure, a polyisoprene structure, a polyisobutylene structure, and a polycarbonate structure. The term “(meth)acrylate” refers to both a methacrylate and an acrylate. These structures may be contained in a main chain or in a side chain of the stress relief material.

From the viewpoint of being able to suppress the warpage, it is preferable that the stress relief material is a high molecular weight material. The number-average molecular weight (Mn) of the stress relief material is preferably 1,000 or more, more preferably 1,500 or more, and still more preferably 2,000 or more, 2,500 or more, 3,000 or more, 4,000 or more, or 5,000 or more. The upper limit of Mn is preferably 1,000,000 or less, more preferably 900,000 or less, and still more preferably 800,000 or less, or 700,000 or less. The number-average molecular weight (Mn) may be measured in terms of polystyrene by a gel permeation chromatography (GPC) method.

From the viewpoint of being able to suppress the warpage, the stress relief material is preferably one or more resins selected from the resins having a glass transition temperature (Tg) of 25° C. or lower and the resins that are in the state of liquid at 25° C. Here, in the resin having multiple Tg values observed, when the lowest Tg thereof is 25° C. or lower, this falls under the category of “the resin having Tg of 25° C. or lower”.

In the resin having Tg of 25° C. or lower, Tg is preferably 20° C. or lower, and more preferably 15° C. or lower. Although there is no particular restriction in the lower limit of Tg, this may be made usually −50° C. or higher. With regard to the resin that is in the state of liquid at 25° C., this is preferably in the state of liquid at 20° C. or lower, and more preferably in the state of liquid at 15° C. or lower.

From the viewpoint of realizing the insulating layer having a high cohesion power (intra-layer adhesion strength) by reacting with a curable resin and the like, it is preferable that the stress relief material has a functional group that is capable of reacting with the curable resin and the like. Note that the functional group that is capable of reacting with the curable resin and the like includes those functional groups that appear upon heating.

In one embodiment, the functional group that is capable of reacting with the curable resin and the like is one or more functional groups selected from the group consisting of a hydroxy group, a carboxy group, an acid anhydride group, a phenolic hydroxy group, an epoxy group, an isocyanate group, and a urethane group. In particular, the functional group is preferably a hydroxy group, an acid anhydride group, a phenolic hydroxy group, an epoxy group, an isocyanate group, and a urethane group; among these, a hydroxy group, an acid anhydride group, a phenolic hydroxy group, and an epoxy group are more preferable. Note that, when the epoxy group is included as the functional group, the number-average molecular weight (Mn) of the material is preferably 5,000 or more.

In one embodiment, the stress relief material includes a resin containing a polybutadiene structure (hereinafter, this is also referred to as “polybutadiene resin”). Note that the polybutadiene structure may be hydrogenated in part or all of it.

Specifically, illustrative examples of the polybutadiene resin include “Ricon 130MA8”, “Ricon 130MA13”, “Ricon 130MA20”, “Ricon 131MA5”, “Ricon 131MA10”, “Ricon 131MA17”, “Ricon 131MA20”, and “Ricon 184MA6” (polybutadiene containing an acid anhydride group), all being manufactured by Cray Valley S.A.; “JP-100” and “JP-200” (epoxidized polybutadiene), “GQ-1000” (polybutadiene having a hydroxy group and a carboxyl group introduced), “G-1000”, “G-2000”, and “G-3000” (polybutadiene terminated with hydroxy groups at both ends), as well as “GI-1000”, “GI-2000”, and “GI-3000” (hydrogenated polybutadiene terminated with hydroxy groups at both ends), all being manufactured by Nippon Soda Co., Ltd.; “PB3600” and “PB4700” (epoxy resin containing a polybutadiene skeleton), as well as “Epofriend A1005”, “Epofriend A10¹⁰”, and “Epofriend A1020” (epoxidized compound of styrene-butadiene-styrene block copolymer), all being manufactured by Daicel Corp.; and “FCA-061L” (epoxy compound containing a hydrogenated polybutadiene skeleton) and “R-45EPT” (epoxy resin containing a polybutadiene skeleton), both being manufactured by Nagase Chemtex Corp. Other examples of the polybutadiene resin include a linear polymer made from, as the raw materials, a polybutadiene terminated with a hydroxy group, a diisocyanate compound, and a tetrabasic acid anhydride (polymer described in Japanese Patent Application Laid-open No. 2006-37083 and International Patent Application Laid-open No. 2008/153208, which are incorporated herein by reference in their entireties), and a butadiene containing a phenolic hydroxy group. The content of the polybutadiene structure in this polymer is preferably 50% by mass or more, and more preferably in the range of 60 to 95% by mass. For details of this polymer, Japanese Patent Application Laid-open No. 2006-37083 and International Patent Application Laid-open No. 2008/153208, which are incorporated herein by reference in their entireties, may be referred, and the contents of these patent literatures are incorporated into this specification.

In one embodiment, the stress relief material includes the resin that contains a poly(meth)acrylate structure (hereinafter this is also referred to as “poly(meth)acrylate resin”). Specifically, illustrative examples of the poly(meth)acrylate resin include Teisan Resin “SG-70L”, “SG-708-6”, “WS-023”, “SG-700AS”, and “SG-280TEA” (acrylate ester copolymer resin containing a carboxy group; the acid number of 5 to 34 mg KOH/g, the weight-average molecular weight of 400,000 to 900,000, the Tg of −30 to 5° C.), “SG-80H”, “SG-80H-3”, and “SG-P3” (acrylate ester copolymer resin containing an epoxy group; the epoxy equivalent of 4761 to 14285 g/eq.; the weight-average molecular weight of 350,000 to 850,000; the Tg of 11 to 12° C.), as well as “SG-600TEA” and “SG-790” (acrylate ester copolymer resin containing a hydroxy group; the hydroxy group value of 20 to 40 mg KOH/g, the weight-average molecular weight of 500,000 to 1,200,000, the Tg of −37 to −32° C.), all being manufactured by Nagase ChemteX Corp.; and “ME-2000” and “W-116.3” (acrylate ester copolymer resin containing a carboxy group), “W-197C” (acrylate ester copolymer resin containing a hydroxy group), “KG-25” and “KG-3000” (acrylate ester copolymer resin containing an epoxy group), all being manufactured by Negami Chemical Industrial Co., Ltd.

In one embodiment, the stress relief material includes the resin containing a polycarbonate structure (hereinafter this is also referred to as “polycarbonate resin”). Specifically, illustrative examples of the polycarbonate resin include “T6002” and “T6001” (polycarbonate diol), both being manufactured by Asahi Kasei Chemicals Corp.; and “C-1090”, “C-2090”, and “C-3090” (polycarbonate diol), all being manufactured by Kuraray Co., Ltd. Also usable is a linear polyimide that is made from, as the raw materials, a polycarbonate terminated with a hydroxy group, a diisocyanate compound, and a tetrabasic acid anhydride. The content of the polycarbonate structure in the polyimide resin is preferably 50% by mass or more, and more preferably in the range of 60 to 95% by mass. For details of the polyimide resin, International Patent Application Laid-open No. 2016-129541, which is incorporated herein by reference in its entirety, may be referred, and the contents of this patent literature are incorporated into this specification.

In one embodiment, the stress relief material includes the resin that contains a polysiloxane structure (hereinafter this is also referred to as “polysiloxane resin”). Specifically, illustrative examples of the polysiloxane resin include “SMP-2006”, “SMP-2003PGMEA”, and “SMP-5005PGMEA”, all being manufactured by Shin-Etsu Chemical Co., Ltd.; and a linear polyimide that is made from, as the raw materials, a polysiloxane terminated with an amino group and a tetrabasic acid anhydride (International Patent Application Laid-open No. 2010/053185, Japanese Patent Application Laid-open No. 2002-12667, Japanese Patent Application Laid-open No. 2000-319386, which are incorporated herein by reference in their entireties, etc.).

In one embodiment, the stress relief material includes the resin that contains a polyalkylene structure or a polyalkyleneoxy structure (hereinafter they are also referred to as “polyalkylene resin” and “polyalkyleneoxy resin”, respectively). Specifically, illustrative examples of the polyalkylene resin and the polyalkyleneoxy resin include “PTXG-1000” and “PTXG-1800”, both being manufactured by Asahi Kasei Fibers Corp.

In one embodiment, the stress relief material includes the resin that contains a polyisoprene structure (hereinafter this is also referred to as “polyisoprene resin”). Specifically, illustrative examples of the polyisoprene resin include “KL-610” and “KL613”, both being manufactured by Kuraray Co., Ltd.

In one embodiment, the stress relief material includes the resin that contains a polyisobutylene structure (hereinafter this is also referred to as “polyisobutylene resin”). Specifically, illustrative examples of the polyisobutylene resin include “SIBSTAR-073T” (styrene-isobutylene-styrene triblock copolymer) and “SIBSTAR-042D” (styrene-isobutylene diblock copolymer), both being manufactured by Kaneka Corp.

In another suitable embodiment, the stress relief material includes an organic filler. A wide range of organic fillers that include a rubber component may be used as the organic filler. Illustrative examples of the rubber component that is included in the organic filler include silicone type elastomers such as polydimethylsiloxane; olefin type thermoplastic elastomers such as polybutadiene, polyisoprene, polychlorobutadiene, ethylene-vinyl acetate copolymer, styrene-butadiene copolymer, styrene-isoprene copolymer, styrene-isobutylene copolymer, acrylonitrile-butadiene copolymer, isoprene-isobutylene copolymer, isobutylene-butadiene copolymer, ethylene-propylene-diene terpolymer, and ethylene-propylene-butene terpolymer; and thermoplastic elastomers such as an acrylic type thermoplastic elastomer, for example, propyl poly(meth)acrylate, butyl poly(meth)acrylate, cyclohexyl poly(meth)acrylate, and octyl poly(meth)acrylate. In addition, the rubber component may be mixed with a silicone type rubber such as a polyorganosiloxane rubber. The rubber component included in the rubber particles has the Tg of, for example, 0° C. or lower, preferably −10° C. or lower, more preferably −20° C. or lower, and still more preferably −30° C. or lower.

In one embodiment, the organic filler is the core-shell type rubber particle consisting of a core particle containing the rubber component as described above and a shell portion formed by graft copolymerization of a monomer component that is copolymerizable with the rubber component contained in the core particle. Note that the core-shell type here does not necessarily refer only to those in which the core particle and the shell portion are clearly distinguishable, but also includes those in which the boundary between the core particle and the shell portion is unclear, and the core particle may not be completely covered by the shell portion.

Specifically, illustrative examples of the organic filler containing the rubber component include “CHT” manufactured by Cheil Industries, Inc.; “B602” manufactured by UMGABS, Ltd.; “Paraloid EXL-2602”, “Paraloid EXL-2603”, “Paraloid EXL-2655”, “Paraloid EXL-2311”, “Paraloid-EXL2313”, “Paraloid EXL-2315”, “Paraloid KM-330”, “Paraloid KM-336P”, and “Paraloid KCZ-201”, all being manufactured by Kureha Corp.; “Metablen C-223A”, “Metablen E 901”, “Metablen S-2001”, “Metablen W-450A”, and “Metablen SRK-200”, all being manufactured by Mitsubishi Rayon Co., Ltd.; “Kane Ace M-511”, “Kane Ace M-600”, “Kane Ace M-400”, “Kane Ace M-580”, and “Kane Ace MR-01”, all being manufactured by Kaneka Corp.; and “STAPHYLOID AC3355”, “STAPHYLOID AC3816”, “STAPHYLOID AC3832”, “STAPHYLOID AC4030”, and “STAPHYLOID AC3364”, all being manufactured by Aica Kogyo Co., Ltd. These are the core-shell type rubber particles.

From the viewpoint of realizing the insulating material that is capable of suppressing the warpage, in the case where the resin composition layer includes the stress relief material, the content of the stress relief material relative to 100% by mass of the resin components in the resin composition is preferably 18 by mass or more, more preferably 2% by mass or more, still more preferably 3% by mass or more, and far still more preferably 4% by mass or more, or 5% by mass or more. In this regard, the inventors of the present invention found that it was possible to suppress the warpage when increasing the content of the stress relief material in the resin composition layer, but it was also found that in the production method of the circuit board that satisfied the condition (ii-1) in combination with the condition (i) so as to suppress the generation of the interface void, the surface potential of the support tended to significantly increase to the level that causes a concern about the damage to the semiconductor chip. On the other hand, according to the production method of the present invention, which satisfies the condition (ii-1) in combination with the condition (i) and further satisfies the condition (ii-2), it is possible to increase the content of the stress relief material furthermore with suppressing the increase in the surface potential of the support. For example, the content of the stress relief material in the resin composition layer relative to 100% by mass of the resin components in the resin composition may be increased to 6% by mass or more, 8% by mass or more, 10% by mass or more, 12% by mass or more, 14% by mass or more, or 15% by mass or more. The upper limit of the content thereof is preferably 40% by mass or less, and more preferably 35% by mass or less, or 30% by mass or less.

Also, the content of the stress relief material in the resin composition layer in terms of the mass ratio of the stress relief material to the sum of the curable resin and the curing agent, namely, stress relief material/[curable resin+curing agent], is preferably 0.05 or more, and more preferably 0.06 or more, 0.08 or more, or 0.1 or more. The upper limit of the mass ratio thereof is preferably 3 or less, and more preferably 2 or less, 1.8 or less, 1.6 or less, or 1.5 or less.

### Curing Accelerator

The resin composition layer may further include a curing accelerator. When the curing accelerator is included in the resin composition, the curing time and the curing temperature may be efficiently controlled.

Illustrative examples of the curing accelerator include organic phosphine compounds such as “TPP”, “TPP-K”, “TPP-S”, and “TPTP-S” (manufactured by Hokko Chemical Industry Co., Ltd.); imidazole compounds such as “Curesol 2MZ”, “2E4MZ”, “C11Z”, “C11Z-CN”, “C11Z-CNS”, “C11Z-A”, “2MZ-OK”, “2MA-OK”, and “2PHZ” (manufactured by Shikoku Chemical Corp.); amine adduct compounds such as “Novacure” (manufactured by Asahi Kasei Corp.) and “Fujicure” (manufactured by Fuji Kasei Co., Ltd.); amine compounds such as 1,8-diazabicyclo [5, 4, 0]undecene-7, 4-dimethylaminopyridine, benzyl dimethylamine, 2,4,6-tris(dimethylaminomethyl) phenol, and 4-dimethylaminopyridine; and organometallic complexes or organometallic salts of the metals such as cobalt, copper, zinc, iron, nickel, manganese, and tin.

In the case where the resin composition layer includes the curing accelerator, although the content of the curing accelerator in the resin composition may be determined in accordance with the properties required for the resin composition, the content of the curing accelerator relative to 100% by mass of the resin components in the resin composition is made preferably 3% by mass or less, more preferably 2% by mass or less, still more preferably 1% by mass or less, and the lower limit thereof may be made 0.001% by mass or more, 0.01% by mass or more, 0.05% by mass or more, or the like.

### Other Additives

The resin sheet of the present invention may further include other additives. Illustrative examples of the additive like this include: radial polymerization initiators such as a peroxide type radial polymerization initiator and an azo type radical polymerization initiator; thermoplastic resins such as a phenoxy resin, a polyvinyl acetal resin, a polysulfone resin, a polyethersulfone resin, a polyphenylene ether resin, a polyether ether ketone resin, and a polyester resin; organic metal compounds such as an organic copper compound, an organic zinc compound, and an organic cobalt compound; coloring materials such as a phthalocyanine blue, a phthalocyanine green, an iodine green, a diazo yellow, a crystal violet, titanium oxide, and carbon black; polymerization inhibitors such as hydroquinone, catechol, pyrogallol, and phenothiazine; leveling agents such as a silicone type leveling agent and an acrylic polymer type leveling agent; thickeners such as bentone and montmorillonite; antifoaming agents such as a silicone type antifoaming agent, an acrylic type antifoaming agent, a fluorine type antifoaming agent, and a vinyl resin type antifoaming agent; UV absorbers such as a benzotriazole type UV absorber; adhesion enhancers such as a urea silane; adhesion assisting agents such as a triazole type adhesion assisting agent, a tetrazole type adhesion assisting agent, and a triazine type adhesion assisting agent; antioxidants such as a hindered phenol type antioxidant; fluorescent whitening agents such as a stilbene derivative; surfactants such as a fluorine type surfactant and a silicone type surfactant; flame retardants such as phosphorous type flame retardants (for example, a phosphate ester compound, a phosphazene compound, a phosphinate compound, and red phosphorus), nitrogen type flame retardants (for example, melamine sulfate), halogen type flame retardants, and inorganic type flame retardants (for example, antimony trioxide); dispersants such as a phosphate ester type dispersant, a polyoxyalkylene type dispersant, an acetylene type dispersant, a silicone type dispersant, an anionic dispersant, and a cationic dispersant; and stabilizers such as a borate type stabilizer, a titanate type stabilizer, an aluminate type stabilizer, a zirconate type stabilizer, an isocyanate type stabilizer, a carboxylate type stabilizer, and a carboxylic anhydride type stabilizer. The content of the additive as described above may be determined in accordance with the properties required for the resin composition layer.

In the resin sheet of the present invention, although the thickness of the resin composition layer may be determined in accordance with a desired design of the circuit board, it may be preferably 50 μm or less, and more preferably 40 μm or less, 35 μm or less, 30 μm or less, 25 μm or less, or 20 μm or less. Although there is no particular restriction in the lower limit of the thickness of the resin composition layer, usually, it may be 1 μm or more, 2 μm or more, 3 μm or more, 5 μm or more, or the like.

From the viewpoint of easiness in handling when laminating on the substrate, the melt viscosity of the resin composition layer at 100° C. is preferably 50,000 poise or less, more preferably 45,000 poise or less, and still more preferably 40,000 poise or less, 35,000 poise or less, or 30,000 poise or less. As mentioned earlier, from the viewpoint of suppressing the warpage, it is preferable for the resin composition layer to include the stress relief material. In this regard, in the case, for example, where the content of stress relief material in the resin composition layer is increased, in the production method of the circuit board that intended to suppress the generation of the interface void by satisfying the condition (ii-1) in combination with the condition (i) as described earlier, when the melt viscosity of the resin composition layer in the lamination temperature range was decreased, the inventors of the present invention found that the surface potential of the support tended to significantly increase to the level that causes a concern about the damage to the semiconductor chip. In contrast, according to the production method of the present invention that satisfies the condition (ii-1) in combination with the condition (i) and also satisfies the condition (ii-2), it is possible to suppress the increase in the surface potential of the support even when the melt viscosity of the resin composition layer is further decreased, for example, by increasing the content of the stress relief material. The melt viscosity of the resin composition layer at 100° C. may be, for example, 25,000 poise or less, 20,000 poise or less, 18,000 poise or less, 16,000 poise or less, 15,000 poise or less, 14,000 poise or less, 12,000 poise or less, or 10,000 poise or less. From the viewpoint of further suppressing the generation of the interface void, the melt viscosity of the resin composition layer at 100° C. is preferably 1,000 poise or more, 1,500 poise or more, or 2,000 poise or more. In the present invention, the melt viscosity of the resin composition layer at 100° C. may be measured in accordance with the method described in the section of “Measurement of Melt Viscosity” to be described later.

### Support

In the resin sheet of the present invention, the support has a first surface and a second surface, and the surface resistivity of the first surface is 1.0×10¹⁰ Ω/sq. or less (“condition (ii-2)” above).

In the present invention, the first surface of the support is the exposed surface that is not bonded to the resin composition layer, and the second surface of the support is the surface that is bonded to the resin composition layer.

As mentioned above, it was found that by using the resin sheet provided with the resin composition layer that satisfied the condition (ii-1) and carrying out the step (X) such that the condition (i) was satisfied, it was possible to suppress the generation of the interface void even when the substrate having a large area was used. On the other hand, a new problem was found that the surface potential of the support was increased to the level that causes a concern about the damage to the semiconductor chip, especially when the substrate had a large area. Also, as described earlier, the problem of the increase in the surface potential tends to be more significant in the composition of the resin composition layer that are formed with the aims to further decrease the dielectric loss tangent and the warpage. By satisfying the condition (ii-2) in combination with the condition (i) and the condition (ii-1), the inventors of the present invention made it possible to suppress the generation of the interface void as well as the increase in the surface potential of the support material even when the insulating material in the form of a resin sheet was applied to the substrate having a large area.

From the viewpoint of suppressing the increase in the surface potential of the support in production of the circuit board, the surface resistivity of the first surface of the support is 1.0×10¹⁰ Ω/sq. or less, preferably 1.0×10⁹ Ω/sq. or less, more preferably 1.0×10⁸ Ω/sq. or less, and still more preferably 5.0×10⁷ Ω/sq. or less, 1.0×10⁷ Ω/sq. or less, 5.0×10⁶ Ω/sq. or less, 1.0×10⁶ Ω/sq. or less, or 5.0×10⁵ Ω/sq. or less. Although there is no particular restriction in the lower limit of the surface resistivity, it may be made usually 1.0×10¹ Ω/sq. or more, 5.0×10¹ Ω/sq. or more, 1.0×10² Ω/sq. or more, or the like. In the present invention, the surface resistivity of the surface of the support may be measured in accordance with the method described in the section of “Measurement of Surface Resistivity” to be described later.

There is no particular restriction in the surface resistivity of the second surface of the support, and it may be, for example, 1.0×10¹⁵ Ω/sq. or less, 1.0×10¹⁴ Ω/sq. or less, 5.0×10¹³ Ω/sq. or less, or the like. However, from the viewpoint of further suppressing the increase in the surface potential of the support, it is preferably 1.0×10¹² Ω/sq. or less, more preferably 1.0×10¹¹ Ω/sq. or less, and still more preferably 1.0×10¹⁰ Ω/sq. or less, 1.0×10⁹ Ω/sq. or less, 1.0×10⁸ Ω/sq. or less, or 5.0×10⁷ Ω/sq. or less. Although there is no particular restriction in the lower limit of the surface resistivity, it may be made usually 1.0×10¹ Ω/sq. or more, 5.0×10¹ Ω/sq. or more, 1.0×10² Ω/sq. or more, or the like.

With regard to the support, there is no particular restriction in the material and composition thereof as long as these satisfy the condition (ii-2) described above. Illustrative examples of the support include a thermoplastic resin film, metal foil, or a release paper. Among them, a thermoplastic resin film is preferable.

In the case where the plastic resin film is used as the support, illustrative examples of the thermoplastic resin include: polyesters such as polyethylene terephthalate (PET) and polyethylene naphthalate (PEN); polycarbonate (PC); acrylic polymers such as poly(methyl methacrylate) (PMMA); a cyclic polyolefin; triacetyl cellulose (TAC); polyether sulfide (PES); polyether ketone; and polyimide. Among these, polyethylene terephthalate and polyethylene naphthalate are preferable.

The support may be subjected to a mat treatment, a corona treatment, or an antistatic treatment on the surface to be bonded to the resin composition layer (second surface). With regard to the support, a release layer-attached support having a release layer attached on the second surface may be used. Illustrative examples of the releasing agent to be used in the release layer of the release layer-attached support may be one or more releasing agents selected from the group consisting of, for example, an alkyd resin, a polyolefin resin, a urethane resin, and a silicone resin.

As described above, in the resin sheet of the present invention, the support is characterized by that the surface resistivity of the first surface thereof is within the desired range (condition (ii-2)).

In order to satisfy the condition (ii-2), it is preferable that the support of the resin sheet of the present invention is subjected to an antistatic treatment. Examples of the antistatic treatment described above include (a) forming an antistatic layer that contains an antistatic agent on the side of the first surface (and the side of the second surface, as needed) of the support, and (b) adding an antistatic agent to the material that constitutes the support.

With regard to the antistatic agent, one or more conventionally known substances selected from the group consisting of a conductive polymer, a conductive particulate, an ionic compound, and a quaternary ammonium salt compound may be used. Illustrative examples of the preferable conductive polymer include a polythiophene type conductive polymer, a polyaniline type conductive polymer, and a polypyrrole type conductive polymer. Illustrative examples of the polythiophene type conductive polymer include polythiophene, poly(3-alkylthiophene), poly(3-thiophene-β-ethanesulfonic acid), and a mixture (including doped mixture) of polyalkylenedioxythiophene and polystyrene sulfonate (PSS). Illustrative examples of the polyaniline type conductive polymer include polyaniline, polymethylaniline, and polymethoxyaniline. Illustrative examples of the polypyrrole type conductive polymer include polypyrrole, poly(3-methylpyrrole), and poly(3-octylpyrrole). Illustrative examples of the preferable conductive particulate include: conductive inorganic particulates such as tin oxide, antimony-doped tin oxide (ATO), indium-tin oxide (ITO), zinc oxide, and antimony pentoxide; particulates having the surface of an organic particulate such as a silicone particulate covered with a conductive compound; and a carbon particulate. Illustrative examples of the preferable ionic compound include a nitrogen-containing onium salt, a sulfur-containing onium salt, a phosphorus-containing onium salt, an alkali metal salt, and an alkali earth metal salt. Illustrative examples of the preferable quaternary ammonium salt compound include: quaternary compounds of a pyrrolidium ring and an alkyl amine, as well as copolymerized products with an acrylate and a methacrylate, a quaternary compound of an N-alkylaminoacrylamide, a vinyl benzyltrimethylammonium salt, and 2-hydroxy-3-methacryloxypropyl trimethylammonium salt.

In the case where the antistatic layer is formed on the side of the first surface of the support (and the side of the second surface, as needed) as the antistatic treatment of the support, it is preferable that the antistatic layer contains a binder component in addition to the antistatic agent. There is no particular restriction in the binder component as long as this component is able to disperse the antistatic agent and to form a film; thus, for example, a curable resin such as a polyester resin, a urethane resin, or an acrylic resin may be used.

There is no particular restriction in the content of the antistatic agent in the antistatic layer as long as it is possible to achieve the desired surface resistivity; thus, this may be determined as appropriate. For example, the content of the antistatic agent relative to 100% by mass of the entire antistatic layer is preferably 0.01% by mass or more, more preferably 0.05% by mass or more, or 0.1% by mass or more, and the upper limit thereof is preferably 50% by mass or less, and more preferably 30% by mass or less.

Accordingly, in one embodiment, in the resin sheet of the present invention, the support is the antistatic layer-attached support in which the antistatic layer is bonded to the first surface of the support.

Hereinafter, examples of the preferable embodiment of the resin sheet of the present invention (layer composition) that uses the antistatic layer-attached support will be described.
(1) resin composition layer/support/antistatic layer
(2) resin composition layer/release layer/support/antistatic layer
(3) resin composition layer/antistatic layer/support/antistatic layer
(4) resin composition layer/release layer/antistatic layer/support/antistatic layer

All of the above (1) to (4) are embodiments that use the antistatic layer-attached support having the antistatic layer bonded to the first surface of the support. In the embodiments (3) and (4) among these embodiments, because the antistatic layer is also formed on the side of the second surface of the support, it is possible to lower the surface resistivity of the second surface of the support as well.

In the case where a release layer is formed on the side of the second surface of the support, the antistatic agent may be added into the release layer to form the release layer having the antistatic property. In this case, the release layer serves also as the antistatic layer.

The antistatic treatment of the support also includes to add the antistatic agent to the material that constitutes the support so as to form the support that exhibits the antistatic property. For example, in the case where the support is a film of a thermoplastic resin, a thermoplastic resin film that exhibits the antistatic property may be formed by adding the antistatic agent into the thermoplastic resin followed by converting it to a film.

Hereinafter, examples of the preferable embodiment of the resin sheet of the present invention (layer composition) using the support that exhibits the antistatic property will be described.
(5) resin composition layer/antistatic support
(6) resin composition layer/release layer/antistatic support

In the resin sheet of the present invention, although there is no particular restriction in the thickness of the support; this is preferably in the range of 5 μm to 75 μm, and more preferably in the range of 10 μm to 60 μm. Note that in the case where the support that is attached with the antistatic layer or with the release layer is used, it is preferable that the total thickness of the support with the antistatic layer or the release layer is within the range described above.

The resin sheet of the present invention may be produced, for example, in such a way that after a resin varnish is prepared by dissolving the resin composition into an organic solvent, the resulting resin varnish is applied onto the side of second surface of the support by using a die coater or the like, and then, this is dried to form the resin composition layer.

Illustrative examples of the organic solvent include: ketones such as acetone, methyl ethyl ketone (MEK), and cyclohexanone; acetate esters such as ethyl acetate, butyl acetate, cellosolve acetate, propyleneglycol monomethyl ether acetate, and carbitol acetate; carbitols such as cellosolve and butyl carbitol; aromatic hydrocarbons such as toluene and xylene; and amide type solvents such as dimethylformamide, dimethylacetamide (DMAc), and N-methylpyrrolidone. The organic solvent may be used singly or as a combination of two or more of those described above.

Drying may be carried out by a known method such as heating or blowing of a hot air. There is no particular restriction in the drying condition. Drying is carried out in such a way as to bring the content of the solvent remained in the resin composition layer to 10% by mass or less, and preferably 5% by mass or less. In the case where the resin varnish containing, for example, 30 to 60% by mass of the organic solvent is used, the resin composition layer may be formed by drying at 50° C. to 150° C. for 3 minutes to 10 minutes, although these conditions vary depending on the boiling point of the organic solvent used in the resin varnish.

As described above, the resin sheet of the present invention includes the support having the first surface and the second surface and the resin composition layer formed on the second surface of the support, and satisfies the following conditions (ii-1) and (ii-2).
(ii-1) a total specific surface area of an inorganic filler in the resin composition layer is 1.5 m²/g or more (in terms of non-volatile components); and
(ii-2) a surface resistivity of the first surface of the support is 1.0×10¹⁰ Ω/sq. or less.

The resin sheet of the present invention described above may be suitably used in the method for producing a circuit board according to the present invention, namely, that includes a step of laminating a resin sheet including a resin composition layer onto a substrate such that the resin composition layer is bonded to the substrate and satisfies condition (i):

(i) an ambient pressure is reduced simultaneously with or prior to bonding the resin composition to the substrate.

With this, even in the case where the method is applied to the substrate having a large area, not only the generation of the interface void but also the increase in the surface potential of the support may be suppressed. Coupled with the inherent feature of the approach of adopting the insulating material in the form of the resin sheet, with which it is easy to form an insulating layer having a highly flat surface even when the composition is modified so as to sufficiently satisfy the properties required to the insulating layer of a circuit board, the resin sheet of the present invention significantly contributes to achieving a further fine wiring while sufficiently satisfying the properties required to the insulating layer of the circuit board.

Other features of the invention will become apparent in the course of the following descriptions of exemplary embodiments which are given for illustration of the invention and are not intended to be limiting thereof.

### EXAMPLES

In the description below, “part” and “%” that describe quantities mean “part by mass” and “% by mass”, respectively, unless otherwise specifically mentioned. The temperature condition, the pressure condition, and the humidity condition are at room temperature (25° C.), an ambient pressure (1 atm), and 50% RH, respectively, unless otherwise specifically mentioned.

First, the measurement and evaluation methods will be described.

### Measurement of Melt Viscosity

The melt viscosity of each resin composition layer of each resin sheet prepared in Examples and Comparative Examples was measured using a dynamic viscoelasticity measurement instrument (“Rheosol-G3000” manufactured by UBM Co., Ltd.). For 1 g of the resin composition sample taken from the resin composition layer, by using a parallel plate having a diameter of 18 mm, the temperature was raised from the starting temperature of 60° C. until 200° C. with the temperature raising rate of 5° C./minute. Here, the dynamic viscoelastic modulus was measured with the temperature measurement interval of 2.5° C., the frequency of 1 Hz, and the strain of 1 deg., thus determining the melt viscosity (poise) at 100° C.

### Measurement of Surface Resistivity

The surface resistivity (Ω/sq.) of each support used in Examples and Comparative Examples was measured using a surface resistivity measurement instrument (double ring electrode method using “ST-4” manufactured by Simco Japan Inc.).

### Evaluation of Interface Void

### (1) Lamination of Resin Sheet

The resin sheet prepared in each of Examples and Comparative Examples was laminated on one side of a substrate in such a way that the resin composition layer came in contact with the substrate by using a sheet laminating machine. In Comparative Example 1, after the resin composition layer was in contact with the substrate, the ambient pressure inside the chamber in which the resin sheet and the substrate to be processed were stored was made to 13 hPa or less by evacuating the air inside the chamber. On the other hand, in Examples 1 to 8 and Comparative Example 2, the resin composition layer came in contact with the substrate after the ambient pressure was made to 13 hPa or less by evacuating the air in the chamber in which the resin sheet and base material to be treated were stored. Then, the resin sheet was laminated onto the substrate by pressing them at the temperature of 100° C. for the period of 100 seconds with the pressure of 0.5 MPa.

In this evaluation, an 8 inch silicon wafer (“8 inch wafer” in Table 1) and a 5 cm square copper-clad laminate (“5 cm sq. CCL” in Table 1) were prepared as the substrates.

### (2) Evaluation of Interface Void

The resulting laminate of the resin sheet with the substrate was observed using an optical microscope (magnification of 150) after the support was peeled off, and this was evaluated with regard to the presence of the void at the interface between the resin composition layer and the substrate in accordance with the following criteria.

### Evaluation Criteria:

◯: there exists no void,
Δ: there exist some voids (the number of voids in the plane is less than 10),
X: there exist some voids (the number of voids in the plane is 10 or more).

### Evaluation of Surface Potential

### (1) Lamination of Resin Sheet

The laminate of the resin sheet with the substrate was obtained in the same manner as in the above <Evaluation of Interface Void>.

### (2) Evaluation of Surface Potential

The surface potential (kV) of the support was measured with regard to the resulting laminate using a surface potential meter (“FMX-004” manufactured by Simco Japan Inc.). Then, the surface potential was evaluated in accordance with the following criteria.

### Evaluation Criteria:

◯: surface potential is 2 kV or less,
Δ: surface potential is more than 2 kV and 4 kV or less,
X: surface potential is more than 4 kV.

### Evaluation of Warpage

### (1) Lamination of Resin Sheet

The laminate of the resin sheet with the substrate was obtained in the same manner as in <Evaluation of Interface Void> above, except that a 12 inch silicon wafer (“12 inch wafer” in Table 1) was used in place of the 8 inch silicon wafer as the substrate.

### (2) Curing of Resin Composition Layer

Then, the resulting laminate was heated in an oven at 180° C. for 90 minutes to cure the resin composition layer. The resulting substrate is referred to as “evaluation substrate A”.

### (3) Evaluation of Warpage

The edge of the resulting evaluation substrate A was pressed down onto a horizontal plate, and the distance between the substrate edge that is on the opposite side of the pressed point and the plate was measured as the amount of the warpage. Then, the warpage was evaluated in accordance with the following criteria.

### Evaluation Criteria of Warpage:

◯: warpage amount of 0 mm or more and 2 mm or less,
X: warpage amount of more than 2 mm.

### Supports Used

The layer structure of each support used in Examples and Comparative Examples are as follows. In the following, the right side of the support (PET film) is the side of the “first surface” and the left side of the support is the side of the “second surface”.

Support 1: PET film/antistatic layer (surface resistivity of the first surface: 1.0×10⁵ Ω/sq., surface resistivity of the second surface: >1.0×10¹³ Ω/sq., thickness: about 38 μm)

Support 2: release layer/PET film/antistatic layer (surface resistivity of the first surface: 1.0×10⁵ Ω/sq., surface resistivity of the second surface: >1.0×10¹³ Ω/sq., thickness: about 38 μm)

Support 3: release layer/antistatic layer/PET film/antistatic layer (surface resistivity of the first surface: 1.0×10⁵ Ω/sq., surface resistivity of the second surface: 1.0×10⁷ Ω/sq., thickness: about 38 μm)

Support 4: release layer/PET film (surface resistivity of the first surface: >1.0×10¹³ Ω/sq., surface resistivity of the second surface: >1.0×10¹³ Ω/sq., thickness: about 38 μm)

### Synthesis Example 1. (Production of Hollow Silica Particle A)

In a reaction vessel, 40 g of methanol, 0.3 g of an aqueous tetramethylammonium hydroxide solution with 25% solid concentration, 0.7 g of dodecyltrimethylammonium chloride, and 0.4 g of hexane were stirred and dissolved. To the resulting methanol solution, 120 g of ion-exchanged water was added to deposit emulsified drops of hexane. Then, after 0.85 g of tetramethoxysilane was added slowly, this was stirred at room temperature (25° C.) for 8 hours and then allowed to mature for 12 hours. Next, after the resulting white precipitate was collected by filtration with a filter paper (5C, manufactured by Advantech Corp.), washed with 300 mL of water, and then, dried at 90° C. for 8 hours to obtain a dry powder of silica particles.

Next, the resulting dry powder was heated to 600° C. with the temperature raising rate of 1° C./min while flowing an air (3 L/min) by using a fast temperature raising electric furnace (“SK-2535E”, manufactured by Motoyama Co., Ltd.), which was then followed by calcinating at 600° C. for 2 hours to remove organic components to obtain the precursor of the hollow silica particle. Next, after 0.5 g of the precursor of the hollow silica particle was transferred to an alumina-made crucible, this was calcined in an electric furnace at 1000° C. for 72 hours, thus obtaining hollow silica particle A (average particle diameter of 1.6 μm, BET specific surface area of 12 m²/g, and porosity of 50% by volume).

### Synthesis Example 2. (Production of Hollow Silica Particle B)

The hollow silica particle B was synthesized by the method described in Japanese Patent No. 5940188.

Specifically, the hollow silica particle B was synthesized with the following procedure.

By spraying 300 g of an aqueous solution of water glass (SiO₂/Na₂O molar ratio of 3.2, SiO₂ concentration of 24% by weight) through one nozzle of the two fluid nozzles with a flow rate of 0.12 kg/hr while blowing a hot air from the other nozzle at the flow rate of 31800 L/hr (air/liquid volume ratio: 31800) with the inlet temperature of 400° C. to obtain the precursor silica-based particle (1). At this time, the outlet temperature was 150° C. Then, 50 g of the precursor silica-based particle (1) was immersed in 500 g of an aqueous sulfuric acid solution with a concentration of 10% by weight, and the resulting mixture was stirred for 2 hours. Next, this was dried in a dryer by heating at 90° C. for 12 hours to obtain the hollow silica particle.

The resulting hollow silica particles were heated to 600° C. at the temperature raising rate of 1° C./min with flowing an air (3 L/min) by using a fast temperature raising electric furnace (“SK-2535E”, manufactured by Motoyama Co., Ltd.), which was then followed by calcinating at 600° C. for 2 hours. Then, after 0.5 g of the hollow silica particles were transferred to an alumina-made crucible, this was calcined in air using the electric furnace at 1000° C. for 72 hours, thus obtaining hollow silica particle B (average particle diameter of 2.0 μm, BET specific surface area of 3.8 m²/g, and porosity of 20% by volume).

### Synthesis Example 3. (Synthesis of Stress Relief Material A)

Into a reaction vessel, 69 g of bifunctional hydroxy group-terminated polybutadiene (“G-3000”; number-average molecular weight of 3000, hydroxy equivalent of 1800 g/eq., manufactured by Nippon Soda Co., Lt.), 40 g of an aromatic hydrocarbon type mixed solvent (“Ipsol 150”, manufactured by Idemitsu Petrochemical Co., Ltd.), and 0.005 g of dibutyltin laurate were added and mixed to dissolve uniformly. After the resulting solution was heated to 60° C., 8 g of isophorone diisocyanate (“IPDI”, manufactured by Evonik Degussa Japan Inc., isocyanate equivalent of 113 g/eq.) was added thereinto with further stirring to carry out the reaction for about 3 hours. With this, the first reaction solution was obtained.

Next, to the resulting first reaction solution, 23 g of cresol novolac resin (“KA-1160”, manufactured by DIC Corp., hydroxy equivalent of 117 g/eq.) and 60 g of ethyl diglycol acetate (manufactured by Daicel Corp.) were added; then, after the temperature of the resulting mixture was raised to 150° C. with stirring, the reaction was carried out for about 10 hours. With this, the second reaction solution was obtained. Disappearance of the NCO peak at 2250 cm-1 was confirmed by FT-IR. The disappearance of the NCO peak was considered to be the endpoint of the reaction; so, the second reaction solution was cooled to room temperature. Next, the second reaction solution was filtrated through a 100 mesh filter cloth. With this, as the filtrate, a solution containing the stress relief material A (polybutadiene resin that contains a phenolic hydroxy group) having a reactive functional group was obtained as the non-volatile component (50% by mass of non-volatile component). The stress relief material A had the number-average molecular weight of 5,900 and the glass transition temperature of −7° C.

### Example 1. Preparation of Resin Sheet 1

### (1) Preparation of Resin Composition

A mixture of 3 parts of a bisphenol A type epoxy resin (“828EL”, manufactured by Mitsubishi Chemical Corp., epoxy equivalent of 189 g/eq.), 4 parts of a naphthylene ether type epoxy resin (“HP6000”, manufactured by DIC Corp., epoxy equivalent of 250 g/eq.), 4 parts of a bixylenol type epoxy resin (“YX4000H”, manufactured by Mitsubishi Chemical Corp., epoxy equivalent of 185 g/eq.), 2 parts of a stress relief material (“Paraloid EXL2655”, manufactured by Dow Chemical Co.), 76 parts of an inorganic filler (spherical silica (“SO-C2”, manufactured by Admatechs Co., Ltd. average particle diameter of 0.5 μm, specific surface area of 5.8 m/g) surface-treated with “KBM573” (amine type silane coupling agent, manufactured by Shin-Etsu Chemical Co., Ltd.)), 3 parts of a phenoxy resin (“YX7553BH30” manufactured by Mitsubishi Chemical Corp., 1:1 solution of MEK and cyclohexanone with 30% by mass of non-volatile content), 3 parts of a phenol type curing agent (“KA-1160”, manufactured by DIC Corp., phenolic hydroxy equivalent of 117 g/eq.), 11 parts of an active ester type curing agent (“HPC-8000-65T”, manufactured by DIC Corp., active ester equivalent of 223 g/eq., solid content of 65% by mass in toluene solution), 0.05 parts of a curing accelerator (4-dimethylaminopyridine (DMAP)), and 15 parts of methyl ethyl ketone was uniformly dispersed using a high-speed rotary mixer to prepare a resin composition varnish.

### (2) Preparation of Resin Sheet

The resulting varnish was uniformly applied onto the second surface of the support 1 such that the thickness of the resin composition layer after drying became 50 μm. Then, the varnish was dried at 80° C. to 120° C. (average temperature of 100° C.) for 4 minutes to obtain the resin sheet 1 which included the support and the resin composition layer on the second surface of the support. In the resin sheet 1 thus obtained, the total specific surface area of the inorganic filler in the resin composition layer was 4.4 m²/g.

### Example 2. Preparation of Resin Sheet 2

The resin sheet 2 was prepared in the same way as in Example 1, except that the support 2 was used in place of the support 1. In the resin sheet 2 thus obtained, the total specific surface area of the inorganic filler in the resin composition layer was 4.4 m²/g.

### Example 3. Preparation of Resin Sheet

The resin sheet 3 was prepared in the same way as in Example 1, except that the support 3 was used in place of the support 1. In the resin sheet 3 thus obtained, the total specific surface area of the inorganic filler in the resin composition layer was 4.4 m²/g.

### Example 4. Preparation of Resin Sheet 4

### (1) Preparation of Resin Composition

The varnish of the resin composition was prepared in the same way as in Example 1, except that (i) the amount of the inorganic filler (spherical silica (“SO-C2”, manufactured by Admatechs Co., Ltd., average particle diameter of 0.5 μm, specific surface area of 5.8 m²/g) surface-treated with “KBM573” (amine type silane coupling agent, manufactured by Shin-Etsu Chemical Co., Ltd.)) was changed from 76 parts to 50 parts, and (ii) 20 parts of an inorganic filler (spherical silica (“UFP-30”, manufactured by Denka Co., Ltd., average particle diameter of 0.3 μm, specific surface area of 30.7 m²/g) surface-treated with “KBM573” (amine type silane coupling agent, manufactured by Shin-Etsu Chemical Co., Ltd.)) was used.

### (2) Preparation of Resin Sheet

The resin sheet 4 was prepared in the same way as in Example 1, except that the support 2 was used in place of the support 1 and the varnish of the resin composition thus prepared was applied to the second surface of the support 2. In the resin sheet 4 thus obtained, the total specific surface area of the inorganic filler in the resin composition layer was 9.6 m²/g.

### Example 5. Preparation of Resin Sheet 5

### (1) Preparation of Resin Composition

A mixture of 3 parts a bisphenol A type epoxy resin (“828EL”, manufactured by Mitsubishi Chemical Corp., epoxy equivalent of 189 g/eq.), 1 part of a naphthylene ether type epoxy resin (“HP6000”, manufactured by DIC Corp., epoxy equivalent of 250 g/eq.), 4 parts a bixylenol type epoxy resin (“YX4000H”, manufactured by Mitsubishi Chemical Corp., epoxy equivalent of 185 g/eq.), 2 parts of a stress relief material (“Paraloid EXL2655”, manufactured by Dow Chemical Co.), 3 parts of a stress relief material (“JP-100”, manufactured by Nippon Soda Co., Ltd., epoxidized polybutadiene resin), 3 parts of the stress relief material A, 76 parts of an inorganic filler (spherical silica (“SO-C2”, manufactured by Admatechs Co., Ltd, average particle diameter of 0.5 μm, specific surface area of 5.8 m²/g) surface-treated with “KBM573” (amine type silane coupling agent, manufactured by Shin-Etsu Chemical Co., Ltd.)), 2 parts of a phenol type curing agent (“KA-1160”, manufactured by DIC Corp., phenolic hydroxy equivalent of 117 g/eq.), 11 parts of an active ester type curing agent (“HPC-8000-65T”, manufactured by DIC Corp., active ester equivalent of 223 g/eq., solid content of 65% by mass in toluene solution), 0.05 parts of a curing accelerator (4-dimethylaminopyridine (DMAP)), and 15 parts of methyl ethyl ketone was uniformly dispersed using a high-speed rotary mixer to prepare a varnish of the resin composition.

### (2) Preparation of Resin Sheet

The resin sheet 5 was prepared in the same way as in Example 1, except that the support 2 was used in place of the support 1 and the varnish of the resin composition thus prepared was applied to the second surface of the support 2. In the resin sheet 5 thus obtained, the total specific surface area of the inorganic filler in the resin composition layer was 4.4 m²/g.

### Example 6. Preparation of Resin Sheet 6

### (1) Preparation of Resin Composition

The varnish of the resin composition was prepared in the same way as Example 1, except that in place of 76 parts of the inorganic filler (spherical silica (“SO-C2”, manufactured by Admatechs Co., Ltd., average particle diameter of 0.5 μm, specific surface area of 5.8 m²/g) surface-treated with “KBM573” (amine type silane coupling agent, manufactured by Shin-Etsu Chemical Co., Ltd.)), 110 parts of an inorganic filler (spherical alumina (average particle diameter of 2 μm, specific surface area 2.1 m²/g) surface-treated with “KBM573”) was used.

### (2) Preparation of Resin Sheet

The resin sheet 6 was prepared in the same way as in Example 1, except that the support 3 was used in place of the support 1 and the varnish of the resin composition thus prepared was applied to the second surface of the support 3. In the resin sheet 6 thus obtained, the total specific surface area of the inorganic filler in the resin composition layer was 1.7 m²/g.

### Example 7. Preparation of Resin Sheet 7

### (1) Preparation of Resin Composition

The varnish of the resin composition was prepared in the same way as in Example 5, except that (i) the amount of the inorganic filler (spherical silica (“SO-C2”, manufactured by Admatechs Co., Ltd., average particle diameter of 0.5 μm, specific surface area of 5.8 m²/g) surface-treated with “KBM573” (amine type silane coupling agent, manufactured by Shin-Etsu Chemical Co., Ltd.)) was changed from 76 parts to 66 parts, and (ii) 10 parts of the hollow silica particle A was used.

### (2) Preparation of Resin Sheet

The resin sheet 7 was prepared in the same way as in Example 1, except that the support 3 was used in place of the support 1 and the varnish of the resin composition thus prepared was applied to the second surface of the support 3. In the resin sheet 7 thus obtained, the total specific surface area of the inorganic filler in the resin composition layer was 5.0 m²/g.

### Example 8. Preparation of Resin Sheet 8

### (1) Preparation of Resin Composition

The varnish of the resin composition was prepared in the same way as Example 5, except that (i) the amount of the inorganic filler (spherical silica (“SO-C2”, manufactured by Admatechs Co., Ltd., average particle diameter of 0.5 μm, specific surface area of 5.8 m²/g) surface-treated with “KBM573” (amine type silane coupling agent, manufactured by Shin-Etsu Chemical Co., Ltd.)) was changed from 76 parts to 66 parts, and (ii) 10 parts of the hollow silica particle B was used.

### (2) Preparation of Resin Sheet

The resin sheet 8 was prepared in the same way as in Example 1, except that the support 3 was used in place of the support 1 and the varnish of the resin composition thus prepared was applied to the second surface of the support 3. In the resin sheet 8 thus obtained, the total specific surface area of the inorganic filler in the resin composition layer was 4.2 m²/g.

### Comparative Example 1. Preparation of Resin Sheet C1

### (1) Preparation of Resin Composition

The varnish of the resin composition was prepared in the same way as in Example 1, except that (i) 2 parts of the stress relief material (“Paraloid EXL2655” manufactured by Dow Chemical Co.) was not used, and (ii) the amount of the inorganic filler (spherical silica (“SO-C2”, manufactured by Admatechs Co., Ltd., average particle diameter of 0.5 μm, specific surface area of 5.8 m²/g) surface-treated with “KBM573” (amine type silane coupling agent, manufactured by Shin-Etsu Chemical Co., Ltd.)) was changed from 76 parts to 20 parts.

### (2) Preparation of Resin Sheet

The resin sheet C1 was prepared in the same way as in Example 1, except that the support 4 was used in place of the support 1 and the varnish of the resin composition thus prepared was applied to the second surface of the support 4. In the resin sheet C1 thus obtained, the total specific surface area of the inorganic filler in the resin composition layer was 2.8 m²/g.

### Comparative Example 2. Preparation of Resin Sheet C2

### (1) Preparation of Resin Composition

The varnish of the resin composition was prepared in the same way as in Example 4, except that 2 parts of the stress relief material (“Paraloid EXL2655” manufactured by Dow Chemical Co.) was not used.

### (2) Preparation of Resin Sheet

The resin sheet C2 was prepared in the same way as in Example 1, except that the support 4 was used in place of the support 1 and the varnish of the resin composition thus prepared was applied to the second surface of the support 4. In the resin sheet C2 thus obtained, the total specific surface area of the inorganic filler in the resin composition layer was 9.8 m²/g.

The results of Examples 1 to 8 and Comparative Examples 1 and 2 are summarized in Table 1 below.

TABLE 1

| | | | | | Non-volatile | | | | | |
|---|---|---|---|---|---|---|---|---|---|---|
| | | | | | component | Examples | | | | |
| | | | | | (% by mass) | 1 | 2 | 3 | 4 | 5 |
| Resin | Resin | Blended | Inorganic | UFP30 | 100 | | | | 20 | |
| sheet | compo- | component | filler | S0-C2 | 100 | 76 | 76 | 76 | 50 | 76 |
| | sition | (part | | Hollow silica A | 100 | | | | | |
| | layer | by mass) | | Hollow silica B | 100 | | | | | |
| | | | | Alumina A | 100 | | | | | |
| | | | Curable | 828EL | 100 | 3 | 3 | 3 | 3 | 3 |
| | | | resin | HP-6000 | 100 | 4 | 4 | 4 | 4 | 1 |
| | | | | YX4000H | 100 | 4 | 4 | 4 | 4 | 4 |
| | | | Curing | KA-1160 | 100 | 3 | 3 | 3 | 3 | 2 |
| | | | agent | HPC-8000-65T | 65 | 11 | 11 | 11 | 11 | 11 |
| | | | Stress | EXL2655 | 100 | 2 | 2 | 2 | 2 | 2 |
| | | | relief | JP-100 | 100 | | | | | 3 |
| | | | material | Stress relief | 50 | | | | | 3 |
| | | | | material A | | | | | | |
| | | | Curing | DMAP | 100 | 0.05 | 0.05 | 0.05 | 0.05 | 0.05 |
| | | | accelerator | | | | | | | |
| | | | Others | YX7553BH30 | 30 | 3 | 3 | 3 | 3 | |

| | | | | | |
|---|---|---|---|---|---|
| Total of non-volatile components | 100.1 | 100.1 | 100.1 | 94.1 | 99.7 |

| | | | | | | |
|---|---|---|---|---|---|---|
| | Content of inorganic filler (% by mass) | 76 | 76 | 76 | 74 | 76 |
| | Total specific surface area of inorganic filler (m²/g) | 4.4 | 4.4 | 4.4 | 9.6 | 4.4 |
| | Melt viscosity at 100° C. (poise) | 10,000 | 10,000 | 10,000 | 30,000 | 5,000 |
| Support | No. | 1 | 2 | 3 | 2 | 2 |

| | | | | | | |
|---|---|---|---|---|---|---|
| Surface resistivity | Second surface | >10\hat{ }13 | >10\hat{ }13 | 10\hat{ }7 | >10\hat{ }13 | >10\hat{ }13 |
| (Ω/sq.) | First surface | 10\hat{ }5 | 10\hat{ }5 | 10\hat{ }5 | 10\hat{ }5 | 10\hat{ }5 |

| Evaluation result | Interface | 8 inch wafer | Result | ∘ | ∘ | ∘ | ∘ | Δ |
|---|---|---|---|---|---|---|---|---|
| | void | 5 cm sq. CCL | Result | ∘ | ∘ | ∘ | ∘ | ∘ |
| | Surface | 8 inch wafer | Potential (kV) | 2 | 2 | 0 | 0 | 3 |
| | potential | | Result | ∘ | ∘ | ∘ | ∘ | Δ |
| | | 5 cm sq. CCL | Potential (kV) | 0 | 0 | 0 | 0 | 0 |
| | | | Result | ∘ | ∘ | ∘ | ∘ | ∘ |
| | Warpage | 12 inch wafer | Result | ∘ | ∘ | ∘ | ∘ | ∘ |

| | | | | | Non-volatile | | | | Comparative | |
|---|---|---|---|---|---|---|---|---|---|---|
| | | | | | component | Examples | | | Examples | |
| | | | | | (% by mass) | 6 | 7 | 8 | 1 | 2 |
| Resin | Resin | Blended | Inorganic | UFP30 | 100 | | | | | 20 |
| sheet | compo- | component | filler | SO-C2 | 100 | | 66 | 66 | 20 | 50 |
| | sition | (part | | Hollow silica A | 100 | | 10 | | | |
| | layer | by mass) | | Hollow silica B | 100 | | | 10 | | |
| | | | | Alumina A | 100 | 110 | | | | |
| | | | Curable | 828EL | 100 | 3 | 3 | 3 | 3 | 3 |
| | | | resin | HP-6000 | 100 | 1 | 1 | 1 | 4 | 4 |
| | | | | YX4000H | 100 | 4 | 4 | 4 | 4 | 4 |
| | | | Curing | KA-1160 | 100 | 2 | 2 | 2 | 3 | 3 |
| | | | agent | HPC-8000-65T | 65 | 11 | 11 | 11 | 11 | 11 |
| | | | Stress | EXL2655 | 100 | 2 | 2 | 2 | | |
| | | | relief | JP-100 | 100 | 3 | 3 | 3 | | |
| | | | material | Stress relief | 50 | 3 | 3 | 3 | | |
| | | | | material A | | | | | | |
| | | | Curing | DMAP | 100 | 0.05 | 0.05 | 0.05 | 0.05 | 0.05 |
| | | | accelerator | | | | | | | |
| | | | Others | YX7553BH30 | 30 | | | | 3 | 3 |

| | | | | | |
|---|---|---|---|---|---|
| Total of non-volatile components | 133.7 | 99.7 | 99.7 | 42.1 | 92.1 |

| | | | | | | |
|---|---|---|---|---|---|---|
| | Content of inorganic filler (% by mass) | 82 | 76 | 76 | 48 | 76 |
| | Total specific surface area of inorganic filler (m²/g) | 1.7 | 5.0 | 4.2 | 2.8 | 9.8 |
| | Melt viscosity at 100° C. (poise) | 3,000 | 7,000 | 5,000 | 500 | 30,000 |
| Support | No. | 3 | 3 | 3 | 4 | 4 |

| | | | | | | |
|---|---|---|---|---|---|---|
| Surface resistivity | Second surface | 10\hat{ }7 | 10\hat{ }7 | 10\hat{ }7 | >10\hat{ }13 | >10\hat{ }13 |
| (Ω/sq.) | First surface | 10\hat{ }5 | 10\hat{ }5 | 10\hat{ }5 | >10\hat{ }13 | >10\hat{ }13 |

| Evaluation result | Interface | 8 inch wafer | Result | ∘ | ∘ | ∘ | x | ∘ |
|---|---|---|---|---|---|---|---|---|
| | void | 5 cm sq. CCL | Result | ∘ | ∘ | ∘ | ∘ | ∘ |
| | Surface | 8 inch wafer | Potential (kV) | 0 | 0 | 0 | 1 | 5 |
| | potential | | Result | ∘ | ∘ | ∘ | ∘ | x |
| | | 5 cm sq. CCL | Potential (kV) | 0 | 0 | 0 | 0 | 0 |
| | | | Result | ∘ | ∘ | ∘ | ∘ | ∘ |
| | Warpage | 12 inch wafer | Result | ∘ | ∘ | ∘ | x | x |

As a result of studying the technique for forming the insulating layer by laminating and curing the resin composition layer on the substrate by using the resin sheet, it was confirmed that the interface void tended to be generated when the area of the substrate was large (Comparative Example 1; in Comparative Example 1, after the resin composition layer and the substrate were in contact with each other, the ambient pressure in the chamber in which the resin sheet and the substrate to be treated were stored was reduced).

As a result of studying the technique to suppress the generation of the interface void even when the insulating material in the form of the resin sheet is applied to the substrate having a large area, it was found that when (a) the ambient pressure was reduced simultaneously with or prior to bonding the resin composition layer to the substrate, and (b) the size and content of the inorganic filler in the resin composition layer were controlled such that the total specific surface area of the inorganic filler was 1.5 m/g or more (in terms of non-volatile components), it was found that it was possible to suppress the generation of the interface void (Comparative Example 2). On the other hand, however, it was found that the surface potential of the support increased especially when the area of the substrate was large (Comparative Example 2). In Comparative Example 2 and Examples 1 to 8, the ambient pressure was reduced to the predetermined value before the resin composition layer and the substrate were bonded, but the same tendency (generation of the interface void can be suppressed but the surface potential of the support increases) was also recognized when the ambient pressure was reduced simultaneously with bonding the resin composition layer to the substrate.

On the other hand, in the production method of the present invention that satisfies all of the aforementioned conditions (i), (ii-1), and (ii-2), even when the insulating material in the form of a resin sheet was applied to the substrate having a large area, it was possible to suppress the generation of the interface void and the increase in the surface potential of the support (Examples 1 to 8).

Where a numerical limit or range is stated herein, the endpoints are included. Also, all values and subranges within a numerical limit or range are specifically included as if explicitly written out.

As used herein the words “a” and “an” and the like carry the meaning of “one or more.”

Obviously, numerous modifications and variations of the present invention are possible in light of the above teachings. It is therefore to be understood that, within the scope of the appended claims, the invention may be practiced otherwise than as specifically described herein.

All patents and other references mentioned above are incorporated in full herein by this reference, the same as if set forth at length.

1. A method for producing a circuit board, the method comprising:
(X) a step of laminating a resin sheet comprising a support having a first surface and a second surface and a resin composition layer formed on the second surface of the support onto a substrate so that the resin composition layer is bonded to the substrate,
the method satisfying the following conditions (i), (ii-1), and (ii-2):
(i) an ambient pressure is reduced simultaneously with or prior to bonding the resin composition layer to the substrate;
(ii-1) a total specific surface area of an inorganic filler in the resin composition layer is 1.5 m²/g or more (in terms of non-volatile components); and
(ii-2) a surface resistivity of the first surface of the support is 1.0×10¹⁰ Ω/sq. or less.

2. The method according to claim 1, wherein the substrate is (a) a semiconductor wafer comprising an electrode pad surface, (b) a carrier substrate on which a plurality of semiconductor chips that are formed by individualizing the semiconductor wafer of (a) are placed with a distance to each other so as to expose the electrode pad surface, (c) a substrate having a sealing resin that seals the semiconductor chips further formed on the carrier substrate of (b), (d) a substrate having a redistribution layer further formed on the sealing resin of the substrate (c), (e) a carrier substrate on which a plurality of the semiconductor chips formed by individualizing the semiconductor wafer of (a) are placed with a distance to each other such that the electrode pad surface faces the carrier substrate, (f) a semiconductor chip-sealed substrate having the electrode pad surface exposed, which is made by peeling off the carrier substrate after further forming a sealing resin that seals the semiconductor chips on the carrier substrate of (e), or (g) a substrate having a redistribution layer further formed on the side of the electrode pad surface of the semiconductor chip-sealed substrate of (f).

3. The method according to claim 1, wherein the substrate is a substrate with a release layer.

4. The method according to claim 1, wherein the main surface size (minimum size) of the substrate is 150 mm or more.

5. The method according to claim 1, comprising, after the step (X), one or more steps selected from:
(1) curing the resin composition layer to form an insulating layer,
(2) perforating the insulating layer,
(3) subjecting the insulating layer to a desmear treatment, and
(4) forming a conductive layer on a surface of the insulating layer.

6. The method according to claim 1, wherein the resin composition layer comprises a stress relief material.

7. The method according to claim 1, wherein the circuit board is a wafer-level package or a panel-level package.

8. A resin sheet used in a method for producing a circuit board, the method including a step of laminating a resin sheet comprising a resin composition layer to a substrate such that the resin composition layer is bonded to a substrate, the method satisfying the following condition (i):
(i) an ambient pressure is reduced simultaneously with or prior to bonding the resin composition layer to the substrate,
the resin sheet comprising:
a support having a first surface and a second surface and a resin composition layer formed on the second surface of the support, wherein
(ii-i) a total specific surface area of an inorganic filler in the resin composition layer is 1.5 m²/g or more (in terms of non-volatile components), and
(ii-2) a surface resistivity of the first surface of the support is 1.0×10¹⁰ Ω/sq. or less.

9. The resin sheet according to claim 8, wherein the main surface size (minimum size) of the substrate is 150 mm or more.

10. The resin sheet according to claim 8, wherein the total specific surface area of the inorganic filler in the resin composition layer is 4.0 m²/g or more (in terms of non-volatile components).

11. The resin sheet according to claim 8, wherein a surface resistivity of the second surface of the support is 1.0×10¹⁰ Ω/sq. or less.

12. The resin sheet according to claim 8, wherein the resin composition layer comprises a stress relief material.

13. The resin sheet according to claim 8, wherein a melt viscosity of the resin composition layer at 100° C. is 50,000 poise or less.
